(19) United States
(12) Patent Application Publication
(10) Pub. No.: US 2011/0089558 A1
(43) Pub. Date: Apr. 21, 2011

(54) SEMICONDUCTOR DEVICE AND A MANUFACTURING METHOD THEREOF

(75) Inventors: Akira MUTO, Kanagawa (JP); Akira Mishima, Mito (JP); Takuro Kanazawa, Hitachinaka (JP); Ochi Kentaro, Hitachi (JP); Tetsuo Iijima, Kanagawa (JP); Katsuo Ishizaka, Kanagawa (JP)

(73) Assignee: RENESAS ELECTRONICS CORPORATION

(21) Appl. No.: 12/906,122

(22) Filed: Oct. 17, 2010

(30) Foreign Application Priority Data
Oct. 19, 2009 (JP) 2009-240806

(51) Int. Cl. H01L 23/36; H01L 21/50; H01L 23/50

(52) U.S. Cl. 257/712; 438/121; 257/723; 257/E21.499; 257/E23.101; 257/E23.079

(57) ABSTRACT

There is provided a technology capable of reducing the mounting burden on the part of a customer which is a recipient of a package. Over a metal board, a single package and another single package are mounted together via an insulation adhesion sheet, thereby to form one composite package. As a result, as compared with the case where six single packages are mounted, the number of packages to be mounted is smaller in the case where three sets of the composite packages are mounted. This can reduce the mounting burden on the part of a customer.

### CROSS-REFERENCE TO RELATED APPLICATIONS

The disclosure of Japanese Patent Application No. 2009-240806 filed on Oct. 19, 2009 including the specification, drawings and abstract is incorporated herein by reference in its entirety.

### BACKGROUND OF THE INVENTION

The present invention relates to a semiconductor device and a manufacturing technology thereof. More particularly, it relates to a technology effectively applicable to a semiconductor device for use in, for example, in-vehicle motor control, and manufacturing thereof.

Japanese Unexamined Patent Publication No. 2008-21796 (Patent Literature 1) describes a package in which an IGBT chip including an IGBT formed therein, and a diode chip including a diode formed therein are sealed by one sealing body.

Japanese Unexamined Patent Publication No. 2004-165281 (Patent Literature 2) describes the following technology: in such a manner as to expose the bottom of a heatsink including a power semiconductor chip mounted over the top surface thereof, the heatsink and the power semiconductor chip are sealed to form a sealing body; and an insulation sheet including a metal layer and an insulation resin layer is fixed thereto so as to be in contact with the portion of the heatsink exposed from the bottom surface of the sealing body.

### CITATION LIST

### Patent Literature

### [PTL 1]

Japanese Unexamined Patent Publication No. 2008-21796

### [PTL 2]

Japanese Unexamined Patent Publication No. 2004-165281

For example, to each phase of a three-phase motor, as switching elements, two IGBTs and two diodes (free wheel diodes) are coupled. Namely, to the three-phase motor, six IGBTs and six diodes are coupled. Herein, for example, when a package obtained by integrating one IGBT and one diode into one package is used, a three-phase motor requires six sets of the packages. The packages are to be mounted in a car on the part of a customer using the packages for in-vehicle motor control. However, mounting of six packages unfavorably causes an increase in working steps, and an increase in material cost for mounting of the packages. In other words, when a single package obtained by integrating one IGBT and one diode into one package is supplied to a customer (e.g., automaker or automotive electric equipment manufacturer), the mounting burden on the part of the customer unfavorably increases.

### SUMMARY OF THE INVENTION

It is an object of the present invention to provide a technology capable of reducing the mounting burden on the part of a customer who is a recipient of packages.

The foregoing and other objects and novel features of the present invention will be apparent from the description of this specification and the accompanying drawings.

Summaries of the representative ones of the inventions disclosed in the present application will be described in brief as follows.

A semiconductor device in accordance with a typical embodiment has: a first package including a first semiconductor chip including a first switching element formed therein and a first diode chip including a first diode formed therein, and a first sealing body, the first semiconductor chip and the first diode chip being sealed with the first sealing body; and a second package including a second semiconductor chip including a second switching element formed therein and a second diode chip including a second diode formed therein, and a second sealing body, the second semiconductor chip and the second diode chip being sealed with the second sealing body. The first package has (a1) a first external coupling emitter electrode protruding from a first side of the first sealing body, (a2) a first external coupling collector electrode protruding from a second side of the first sealing body opposite to the first side thereof, and (a3) a first external coupling gate electrode protruding from the first side of the first sealing body. The second package has (b1) a second external coupling emitter electrode protruding from a first side of the second sealing body, (b2) a second external coupling collector electrode protruding from a second side of the second sealing body opposite to the first side thereof, and (b3) a second external coupling gate electrode protruding from the first side of the second sealing body. With this configuration, the semiconductor device includes: (c) a metal board including an insulation layer formed over the surface thereof; (d) the first package mounted over the insulation layer via an insulation adhesion layer; (e) the second package mounted over the insulation layer via the insulation adhesion layer; and (f) a metal board fixing screw hole formed in the metal board.

Further, a semiconductor device in accordance with another typical embodiment has: a first package including a first semiconductor chip including a first switching element formed therein and a first diode chip including a first diode formed therein, and a first sealing body, the first semiconductor chip and the first diode chip being sealed with the first sealing body; and a second package including a second semiconductor chip including a second switching element formed therein and a second diode chip including a second diode formed therein, and a second sealing body, the second semiconductor chip and the second diode chip being sealed with the second sealing body. The first package has (a1) a first external coupling emitter electrode protruding from a first side of the first sealing body, (a2) a first external coupling collector electrode protruding from a second side of the first sealing body opposite to the first side thereof, and (a3) a first external coupling gate electrode protruding from the first side of the first sealing body. The second package has (b1) a second external coupling emitter electrode protruding from a first side of the second sealing body, (b2) a second external coupling collector electrode protruding from a second side of the second sealing body opposite to the first side thereof, and (b3) a second external coupling gate electrode protruding from the first side of the second sealing body. With this configuration, the semiconductor device includes: (c) a metal board; (d) a first insulation sheet mounted over the metal board; (e) the first package mounted over the first insulation sheet; and (f) the second package mounted over the first insulation sheet. Further, the semiconductor device includes: (g) a pressing plate disposed across over the first package and over the second package; (h) a metal board fixing screw hole formed in the metal board; (i) a first pressing plate fixing screw hole formed in the metal board; and (j) a second pressing plate fixing screw hole formed in the pressing plate. Then, the semiconductor device includes (k) a pressing plate fixing screw to be inserted into both of the first pressing plate fixing screw hole and the second pressing plate fixing screw hole, for fixing the pressing plate to the metal board.

A method for manufacturing a semiconductor device in accordance with a typical embodiment includes the steps of: (a) preparing a first package including a first semiconductor chip including a first switching element formed therein and a first diode chip including a first diode formed therein, and a first sealing body, the first semiconductor chip and the first diode chip being sealed with the first sealing body; and (b) preparing a second package including a second semiconductor chip including a second switching element formed therein and a second diode chip including a second diode formed therein, and a second sealing body, the second semiconductor chip and the second diode chip being sealed with the second sealing body. Then, the method includes the steps of: (c) preparing a metal board including an insulation layer over the surface thereof; and (d) forming an insulation adhesion layer over the insulation layer formed over the metal board. Further, the method includes the steps of: (e) mounting the first package and the second package over the insulation adhesion layer; and (f) curing the insulation adhesion layer, and thereby bonding the insulation layer with the first package, and the insulation layer with the second package.

Further, a method for manufacturing a semiconductor device in accordance with another typical embodiment includes the steps of: (a) preparing a first package including a first semiconductor chip including a first switching element formed therein and a first diode chip including a first diode formed therein, and a first sealing body, the first semiconductor chip and the first diode chip being sealed with the first sealing body; and (b) preparing a second package including a second semiconductor chip including a second switching element formed therein and a second diode chip including a second diode formed therein, and a second sealing body, the second semiconductor chip and the second diode chip being sealed with the second sealing body. Then, the method includes the steps of: (c) preparing a metal board including a metal board fixing screw hole and a first pressing plate fixing screw hole formed therein; (d) mounting an insulation sheet over the metal board; and (e) mounting the first package and the second package over the insulation sheet. Further, the method includes a step of: (f) mounting a pressing plate including a second pressing plate fixing screw hole formed therein across over the first package and over the second package, and disposing the pressing plate such that the second pressing plate fixing screw hole overlaps the first pressing plate fixing screw hole in plan view. Subsequently, the method includes a step of (g) inserting a pressing plate fixing screw into the second pressing plate fixing screw hole and the first pressing plate fixing screw hole, and fixing the pressing plate to the metal board.

Still further, a method for manufacturing a semiconductor device in accordance with a still further typical embodiment relates to a method for manufacturing a semiconductor device, the device having: a first package including a first semiconductor chip including a first switching element formed therein and a first diode chip including a first diode formed therein, and a first sealing body, the first semiconductor chip and the first diode chip being sealed with the first sealing body; and a second package including a second semiconductor chip including a second switching element formed therein and a second diode chip including a second diode formed therein, and a second sealing body, the second semiconductor chip and the second diode chip being sealed with the second sealing body. Specifically, in this semiconductor device, the first package has a first external coupling emitter electrode protruding from a first side of the first sealing body, a first external coupling collector electrode protruding from a second side of the first sealing body opposite to the first side thereof, and a first external coupling gate electrode protruding from the first side of the first sealing body. The second package has a second external coupling emitter electrode protruding from a first side of the second sealing body, a second external coupling collector electrode protruding from a second side of the second sealing body opposite to the first side thereof, and a second external coupling gate electrode protruding from the first side of the second sealing body. The method for manufacturing a semiconductor device thus configured includes the following steps (a) to (e). (a) There is prepared the first package in which the bottom surface of a first heat spreader including the first semiconductor chip and the first diode chip mounted thereover, and electrically coupled with the first external coupling collector electrode is exposed from the bottom surface of the first sealing body. In the first package, the top surface of a first conductive member directly or indirectly coupled with the first semiconductor chip and the first diode chip, and electrically coupled with the first external coupling emitter electrode is exposed from the top surface of the first sealing body opposite to the bottom surface thereof. Then, (b) there is prepared the second package in which the bottom surface of a second heat spreader including the second semiconductor chip and the second diode chip mounted thereover, and electrically coupled with the second external coupling collector electrode is exposed from the bottom surface of the second sealing body. In the second package, the top surface of a second conductive member directly or indirectly coupled with the second semiconductor chip and the second diode chip, and electrically coupled with the second external coupling emitter electrode is exposed from the top surface of the second sealing body opposite to the bottom surface thereof. Subsequently, (c) there is prepared a metal board including a metal board fixing screw hole and a first pressing plate fixing screw hole formed therein. Thereafter, (d) a first insulation sheet is mounted over the metal board; and (e) the first package and the second package are mounted over the first insulation sheet such that the bottom surface of the first package and the bottom surface of the second package are in contact with the first insulation sheet. Further, the method includes the following steps (f) and (g). (f) A second insulation sheet is mounted across over the top surface of the first package and over the top surface of the second package; and (g) a pressing plate including a second pressing plate fixing screw hole formed therein is mounted over the second insulation sheet, and the pressing plate is disposed such that the second pressing plate fixing screw hole overlaps the first pressing plate fixing screw hole in plan view. Then, the method includes the following step. (h) A pressing plate fixing screw is inserted into the second pressing plate fixing screw hole and the first pressing plate fixing screw hole, thereby to fix the pressing plate to the metal board.

The effects obtainable by the typical ones out of the inventions disclosed in the present application will be briefly described as follows.

Integration into a composite package eliminates the necessity for a customer who is a recipient of the package to mount a plurality of single packages, resulting in a reduction of the mounting burden on the part of the customer.

### BRIEF DESCRIPTION OF THE DRAWINGS

FIG. 1 is a view showing a circuit diagram of a three-phase motor in Embodiment 1 of the present invention;

FIG. 2 is a perspective view of a single package in Embodiment 1 as seen from the outer front surface side;

FIG. 3 is a perspective view of the single package in Embodiment 1 as seen from the outer back surface side;

FIG. 4 is a plan view showing the inside of the single package;

FIG. 5 is a cross-sectional view cut along line A-A of FIG. 4;

FIG. 6 is a circuit diagram showing one example of a circuit formed in a semiconductor chip;

FIG. 7 is a plan view showing a configuration of a composite package in Embodiment 1;

FIG. 8 is a side view showing a configuration of the composite package in Embodiment 1;

FIG. 9 is a cross-sectional view cut along line A-A of FIG. 7;

FIG. 10 is a plan view showing a configuration of a composite package in a modified example;

FIG. 11 is a side view showing a configuration of the composite package in the modified example;

FIG. 12 is a flowchart showing manufacturing steps of a composite package in Embodiment 2;

FIG. 13A is a plan view showing a manufacturing step of the composite package in Embodiment 2, and FIG. 13B is a cross-sectional view showing the manufacturing step of the composite package in Embodiment 2;

FIG. 14A is a plan view showing a manufacturing step of the composite package in Embodiment 2, and FIG. 14B is a cross-sectional view showing the manufacturing step of the composite package in Embodiment 2;

FIG. 15A is a plan view showing a manufacturing step of the composite package in Embodiment 2, and FIG. 15B is a cross-sectional view showing the manufacturing step of the composite package in Embodiment 2;

FIG. 16 is a plan view showing a configuration of a composite package in Embodiment 3;

FIG. 17 is a side view showing a configuration of the composite package in Embodiment 3;

FIG. 18 is a cross-sectional view cut along line A-A of FIG. 16;

FIG. 19 is a photograph showing a configuration of an insulation adhesion sheet;

FIG. 20 is a plan view showing a configuration of a composite package in a modified example;

FIG. 21 is a side view showing a configuration of the composite package in the modified example;

FIG. 22 is a flowchart showing manufacturing steps of a composite package in Embodiment 4;

FIG. 23A is a plan view showing a manufacturing step of the composite package in Embodiment 4, and FIG. 23B is a cross-sectional view showing the manufacturing step of the composite package in Embodiment 4, and is a cross-sectional view cut along line A-A of FIG. 23A;

FIG. 24A is a plan view showing a manufacturing step of the composite package in Embodiment 4, and FIG. 24B is a cross-sectional view showing the manufacturing step of the composite package in Embodiment 4, and is a cross-sectional view cut along line A-A of FIG. 24A;

FIG. 25A is a plan view showing a manufacturing step of the composite package in Embodiment 4, and FIG. 25B is a cross-sectional view showing the manufacturing step of the composite package in Embodiment 4, and is a cross-sectional view cut along line A-A of FIG. 25A;

FIG. 26A is a plan view showing a manufacturing step of the composite package in Embodiment 4, and FIG. 26B is a cross-sectional view showing the manufacturing step of the composite package in Embodiment 4, and is a cross-sectional view cut along line A-A of FIG. 26A;

FIG. 27A is a plan view showing a manufacturing step of the composite package in Embodiment 4, and FIG. 27B is a cross-sectional view showing the manufacturing step of the composite package in Embodiment 4, and is a cross-sectional view cut along line A-A of FIG. 27A;

FIG. 28 is a perspective view of a single package in Embodiment 5 as seen from the outer front surface side;

FIG. 29 is a perspective view of the single package in Embodiment 5 as seen from the outer back surface side;

FIG. 30 is a plan view showing a configuration of a composite package in Embodiment 5;

FIG. 31 is a side view showing a configuration of the composite package in Embodiment 5;

FIG. 32 is a cross-sectional view cut along line A-A of FIG. 30;

FIG. 33 is a plan view showing a configuration of a composite package in a modified example;

FIG. 34 is a side view showing a configuration of the composite package in a modified example;

FIG. 35 is a plan view showing a configuration of a composite package in Embodiment 6;

FIG. 36 is a side view showing a configuration of the composite package in Embodiment 6;

FIG. 37 is a cross-sectional view cut along line A-A of FIG. 35;

FIG. 38 is a plan view showing a configuration of a composite package in a modified example;

FIG. 39 is a side view showing a configuration of the composite package in the modified example;

FIG. 40 is a flowchart showing manufacturing steps of a composite package in Embodiment 7;

FIG. 41A is a plan view showing a manufacturing step of the composite package in Embodiment 7, and FIG. 41B is a cross-sectional view showing the manufacturing step of the composite package in Embodiment 7, and is a cross-sectional view cut along line A-A of FIG. 41A;

FIG. 42A is a plan view showing a manufacturing step of the composite package in Embodiment 7, and FIG. 42B is a cross-sectional view showing the manufacturing step of the composite package in Embodiment 7, and is a cross-sectional view cut along line A-A of FIG. 42A;

FIG. 43A is a plan view showing a manufacturing step of the composite package in Embodiment 7, and FIG. 43B is a cross-sectional view showing the manufacturing step of the composite package in Embodiment 7, and is a cross-sectional view cut along line A-A of FIG. 43A;

FIG. 44A is a plan view showing a manufacturing step of the composite package in Embodiment 7, and FIG. 44B is a cross-sectional view showing the manufacturing step of the composite package in Embodiment 7, and is a cross-sectional view cut along line A-A of FIG. 44A;

FIG. 45A is a plan view showing a manufacturing step of the composite package in Embodiment 7, and FIG. 45B is a cross-sectional view showing the manufacturing step of the composite package in Embodiment 7, and is a cross-sectional view cut along line A-A of FIG. 45A;

FIG. 46A is a plan view showing a manufacturing step of the composite package in Embodiment 7, and FIG. 46B is a cross-sectional view showing the manufacturing step of the composite package in Embodiment 7, and is a cross-sectional view cut along line A-A of FIG. 46A;

FIG. 47 is a plan view showing a configuration of a composite package in Embodiment 8;

FIG. 48 is a plan view showing a configuration of a composite package in Embodiment 9;

FIG. 49 is a plan view showing a mounting example of a power semiconductor device;

FIG. 50 is a plan view showing a mounting example of a power semiconductor device;

FIG. 51 is a plan view showing a mounting example of a power semiconductor device; and

FIG. 52 is a cross-sectional view cut along line A-A of FIG. 49.

### DESCRIPTION OF THE PREFERRED EMBODIMENTS

In the following embodiment, the embodiment may be described in a plurality of divided sections or embodiments for convenience, if required. However, unless otherwise specified, these are not independent of each other, but are in a relation such that one is a modification example, details, complementary explanation, or the like of a part or the whole of the other.

Further, in the following embodiments, when a reference is made to the number of elements, and the like (including number, numerical value, quantity, range, or the like), unless otherwise specified, or except the case where the number is apparently limited to a specific number in principle, the number of elements is not limited to the specific number, but may be greater than or less than the specific number.

Further, in the following embodiments, it is naturally understood that the constitutional elements (including element steps, or the like) are not always essential, unless otherwise specified, or except the case where they are apparently considered essential in principle, or except for other cases.

Similarly, in the following embodiments, when a reference is made to the shapes, positional relationships, or the like of the constitutional elements, or the like, it is understood that they include ones substantially analogous or similar to the shapes or the like, unless otherwise specified, or unless otherwise considered apparently in principle, or except for other cases. This also applies to the foregoing numerical values and ranges.

Whereas, in all the drawings for describing the embodiments, the same members are given the same reference signs and numerals in principle, and a repeated description thereon is omitted. Incidentally, for ease of understanding of the drawings, hatching may be provided even in a plan view.

### Embodiment 1

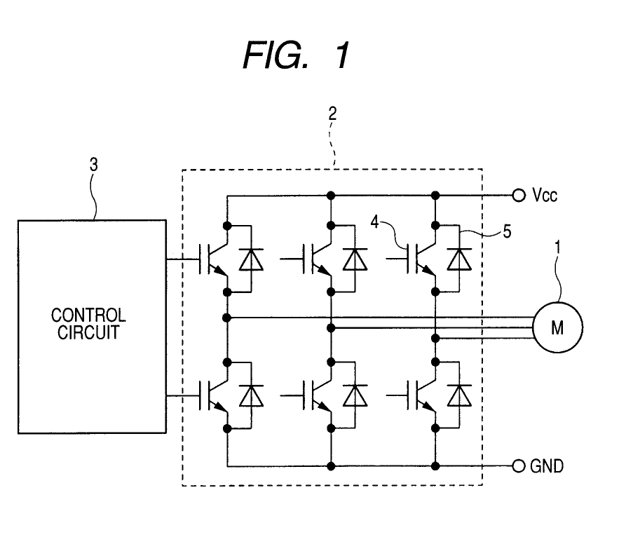

A semiconductor device of Embodiment 1 is for use in a driving circuit of a three-phase motor to be used for, for example, a hybrid car. FIG. 1 is a view showing the circuit diagram of a three-phase motor in Embodiment 1. In FIG. 1, the three-phase motor circuit has a three-phase motor 1, a power semiconductor device 2, and a control circuit 3. The three-phase motor 1 is driven by three-phase voltages different in phase. The power semiconductor device 2 includes switching elements for controlling the three-phase motor 1, and is provided therein with, for example, IGBTs 4 and diodes 5 corresponding to the three phases. Namely, in each single phase, between the power supply potential (Vcc) and the input potential of the three-phase motor, the IGBT 4 and the diode 5 are anti-parallel coupled to each other. Whereas, between the input potential of the three-phase motor and the ground potential (GND), the IGBT 4 and the diode 5 are also anti-parallel coupled to each other. In other words, in the three-phase motor 1, each single phase (each phase) is provided with two IGBTs 4 and two diodes 5. Thus, three phases are provided with six IGBTs 4 and six diodes 5. Then, to the gate electrode of each individual IGBT 4, although partially not shown, the control circuit 3 is coupled. The control circuit 3 controls the IGBTs 4. In the driving circuit of the three-phase motor 1 thus configured, the control circuit 3 controls the current flowing through the IGBTs 4 (switching elements) forming the power semiconductor device 2, which rotates the three-phase motor 1. In other words, the IGBT 4 functions as a switching element supplying the power supply potential (Vcc) to the three-phase motor 1, or supplies the ground potential (GND) thereto. Control of the timing of ON/OFF of the IGBT 4 by the control circuit 3 can drive the three-phase motor 1.

Then, the IGBT 4 and the diode 5 are, as shown in FIG. 1, anti-parallel coupled to each other. The function of the diode 5 in this case will be described.

The diode 5 is unnecessary when the load is a pure resistance not including an inductance. This is because there is no return energy in such a case. However, when the load is coupled with a circuit including an inductance such as a motor (e.g., three-phase motor), there is a mode in which a load current flows in the opposite direction to the direction of current flow through the switch (IGBT 4) in ON state. In this case, a single switching element such as the IGBT 4 has no function of allowing the reverse current to flow. Therefore, a diode is required to be anti-parallel coupled with the switching element such as the IGBT 4. Namely, in the case where in the inverter circuit, the load includes an inductance as with motor control, when the switching element such as the IGBT 4 is turned off, the energy (½LI²) stored in inductance must be necessarily released. The single IGBT 4 cannot allow a flow of a reverse current for releasing the energy stored in the inductance. Thus, in order to return the electric energy stored in the inductance, the diode 5 is anti-parallel coupled to the IGBT 4. In other words, the diode 5 has a function of allowing a flow of a reverse current for releasing the electric energy stored in the inductance. Incidentally, it is also necessary to impart the high-frequency characteristics to the diode 5 according to the switching frequency of the IGBT 4.

The power semiconductor device 2 thus configured is formed in a package. The semiconductor device in Embodiment 1 relates to the packaging technology of the power semiconductor device 2 of FIG. 1. For example, there is a technology of integrating one IGBT 4 and one diode 5 forming the power semiconductor device 2 into one package, and thereby forming a single package. Namely, using six sets of the single packages in Embodiment 1, it is possible to form the power semiconductor device 2 for driving the three-phase motor 1. Below, the configuration of the single package will be described.

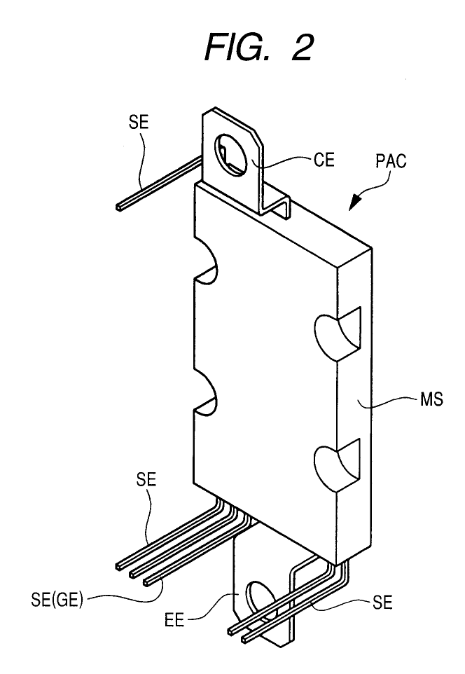

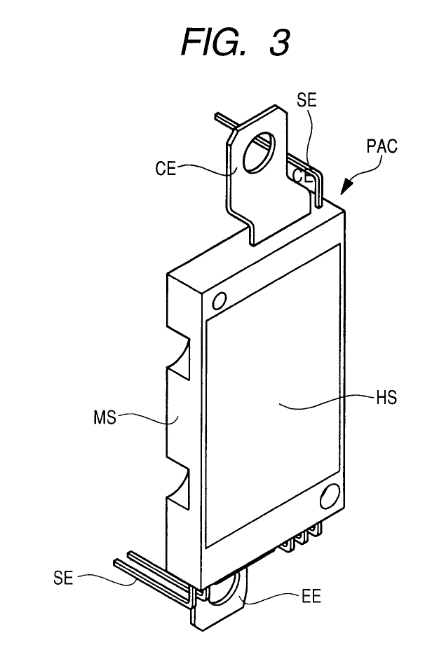

FIG. 2 is a perspective view of a single package PAC in Embodiment 1 as seen from the outer front surface side. In FIG. 2, in the central part of the single package PAC, there is formed a sealing body MS in the shape of generally a rectangle in plan view. On the side of a second side of the top of the sealing body MS, an external coupling collector electrode CE and some of signal electrodes SE are disposed. Then, on the side of a first side of the sealing body MS opposite to the second side thereof at which the external coupling collector electrode CE is formed, an external coupling emitter electrode EE and others of the signal electrodes SE are formed. FIG. 3 is a perspective view of the single package PAC as seen from the outer back surface side. As shown in FIG. 3, on the back surface side of the sealing body MS, a heat spreader HS is exposed. Thus, the heat spreader HS is exposed from the back surface of the sealing body MS. This is in order to improve the heat radiation efficiency of the single package PAC.

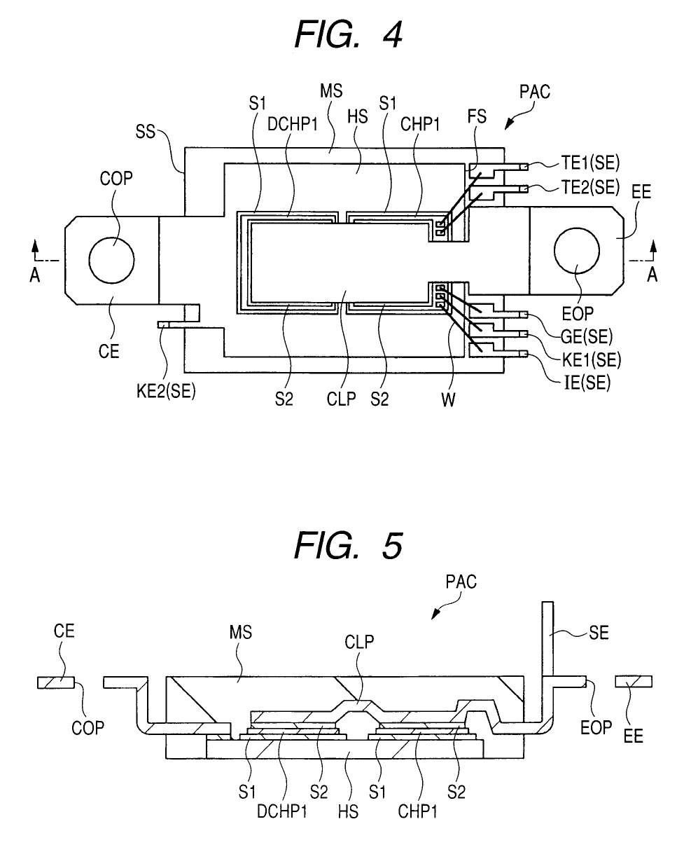

Then, the internal structure of the single package PAC will be described. FIG. 4 is a plan view showing the inside of the single package PAC. Whereas, FIG. 5 is a cross-sectional view showing the cross section cut along line A-A of FIG. 4. Incidentally, in FIG. 4, a part of the sealing body MS covering the top surface of the single package PAC is not shown, and the structure of the inside is shown.

In FIGS. 4 and 5, in the inside of the sealing body MS in the shape of a rectangle, the heat spreader HS is disposed. The heat spreader HS is coupled with the external coupling collector electrode CE. The external coupling collector electrode CE is exposed from the sealing body MS. In the external coupling collector electrode CE, a screw opening COP is disposed.

Over the heat spreader HS, a semiconductor chip (first semiconductor chip) CHP1 including an IGBT formed therein is formed via a solder S1. A semiconductor chip (second semiconductor chip) DCHP1 including a diode formed therein is formed in such a manner as to be adjacent to the semiconductor chip CHP1 including an IGBT formed therein via the solder S1. On the back surface side of the semiconductor chip CHP1 including an IGBT formed therein, a collector electrode is formed. The collector electrode is coupled to the heat spreader HS via the solder S1. In other words, the collector electrode formed on the back surface of the semiconductor chip CHP1 is electrically coupled with the external coupling collector electrode CE via the heat spreader HS. On the other hand, on the back surface side of the semiconductor chip DCHP1 including a diode formed therein, a cathode electrode is formed. The cathode electrode is electrically coupled with the external coupling collector electrode CE via the heat spreader HS. This results in that the collector electrode of the IGBT and the cathode electrode of the diode are electrically coupled with each other.

On the other hand, on the top surface (main surface) side of the semiconductor chip CHP1 including an IGBT formed therein, an emitter electrode and a plurality of bonding pads are formed. In contrast, on the top surface (main surface) side of the semiconductor chip DCHP1 including a diode formed therein, an anode electrode is formed. Then, the emitter electrode formed on the top surface side of the semiconductor chip CHP1 including an IGBT formed therein, and the anode electrode formed on the top surface side of the semiconductor chip DCHP1 including a diode formed therein are coupled with each other by a plate-like clip CLP via a solder S2. Therefore, the emitter electrode of the IGBT and the anode electrode of the diode are electrically coupled with each other by the clip CLP. The clip CLP is also referred to as a plate-like electrode. Below, as the plate-like electrode, the term “clip CLP” will be used. Further, the main surface of the semiconductor chip CHP1 including an IGBT formed therein means the top surface of the semiconductor chip CHP1 including an IGBT formed therein. Namely, the main surface of the semiconductor chip CHP1 including an IGBT formed therein denotes the surface of the semiconductor chip CHP1 opposite to the surface thereof in contact with the heat spreader HS. Similarly, the main surface of the semiconductor chip DCHP1 including a diode formed therein means the top surface of the semiconductor chip DCHP1 including a diode formed therein. Namely, the main surface of the semiconductor chip DCHP1 including a diode formed therein denotes the surface of the semiconductor chip DCHP1 opposite to the surface thereof in contact with the heat spreader HS.

The clip CLP includes, for example, a plate-like member including copper as a main component. The clip CLP electrically couples the emitter electrode of the semiconductor chip CHP1 including an IGBT formed therein, and the anode electrode of the semiconductor chip DCHP1 including a diode formed therein. In the related art, the emitter electrode of the semiconductor chip CHP1 including an IGBT formed therein, and the anode electrode of the semiconductor chip DCHP1 including a diode formed therein are often coupled by a wire including aluminum as a main component. However, a large electric current flows through the emitter electrode. Therefore, with the wire including aluminum as a main component, the ON resistance unfavorably increases due to an increase in resistance by aluminum, an increase in resistance by the thin line, and the like. Further, the wire is a thin line, and hence the heat capacity is small, which unfavorably causes deterioration of the heat radiation characteristics. Thus, according to Embodiment 1, the emitter electrode of the semiconductor chip CHP1 including an IGBT formed therein and the anode electrode of the semiconductor chip DCHP1 including a diode formed therein are coupled with each other by the plate-like clip CLP including copper as a main component. The resistance of copper is smaller than the resistance of aluminum. Therefore, coupling by the clip CLP including copper as a main component can reduce the ON resistance. Further, the clip CLP is in the shape of a wide plate, and hence, has a larger cross-sectional area than that of a wire. For this reason, use of the clip CLP can further reduce the ON resistance. Further, the clip CLP is in the shape of a plate, and hence, the heat capacity possessed by the clip CLP itself can be made larger than the heat capacity of the wire itself. In addition, the contact area between the semiconductor chip CHP1 or the semiconductor chip DCHP1 and the clip CLP can be made larger than that with coupling by a wire. Therefore, the heat radiation efficiency can be improved.

The external coupling emitter electrode EE is formed in such a manner as to be integrated with the clip CLP. The external coupling emitter electrode EE is formed on the side of a first side FS of the heat spreader HS opposite to the side of a second side SS thereof coupled with the external coupling collector electrode CE, and is not electrically coupled with the heat spreader HS. Namely, when the external coupling emitter electrode EE is coupled with the heat spreader HS, the external coupling collector electrode CE is directly coupled with the external coupling emitter electrode EE. Therefore, there is adopted such a configuration so as to prevent a short-circuit. In other words, the external coupling emitter electrode EE is coupled with the emitter electrode of the semiconductor chip CHP1 including an IGBT formed therein via the clip CLP. In the external coupling emitter electrode EE, a screw opening EOP is also formed as with the external coupling collector electrode CE.

On the side of the first side FS of the heat spreader HS at which the external coupling emitter electrode EE is formed, and on the side of the second side SS opposite to the first side FS, signal electrodes SE shown in FIGS. 2 and 3 are formed. FIG. 4 specifically shows the signal electrodes SE. As shown in FIG. 4, on the side of the first side FS of the heat spreader HS, other than the external coupling emitter electrode EE, there are formed a temperature detecting electrode TE1, a temperature detecting electrode TE2, an external coupling gate electrode GE, a Kelvin detecting electrode KE1, and a current detecting electrode IE.

The clip CLP is disposed in such a manner as to be interposed between the signal electrodes SE. Herein, the clip CLP is interposed between the temperature detecting electrode TE2 and the external coupling gate electrode GE. Such arrangement makes the route between the clip CLP and the integrated external coupling emitter electrode EE shorter and linear. Therefore, as compared with the case of the arrangement such that the clip CLP is not interposed between the signal electrodes SE, and extends in a circuitous path, the ON resistance can be reduced. Incidentally, the arrangement of the clip CLP is not limited to the arrangement in which the clip CLP is disposed between the temperature detecting electrode TE2 and the external coupling gate electrode GE. The clip CLP may be disposed between other signal electrodes SE.

The signal electrodes SE are coupled with the bonding pads formed over the top surface of the semiconductor chip CHP1 including an IGBT formed therein, respectively, using wires W in the sealing body MS. Therefore, the semiconductor chip CHP1 including an IGBT formed therein is disposed on the side closer to the first side FS of the heat spreader HS than the semiconductor chip DCHP1 including a diode formed therein. With such arrangement, it is possible to dispose the bonding pads formed over the semiconductor chip CHP1 in proximity to the temperature detecting electrodes TE1 and TE2, the external coupling gate electrode GE, the Kelvin detecting electrode KE1, and the current detecting electrode IE. This facilitates coupling between the bonding pads and the electrodes by the wires W. Further, on the side of the second side SS of the heat spreader HS opposite to the first side FS thereof, the Kelvin detecting electrode KE2 to be coupled with the external coupling collector electrode CE is formed.

Then, FIG. 5 is a cross-sectional view showing the cross section cut along line A-A of FIG. 4. As shown in FIG. 5, over the heat spreader HS, the semiconductor chip CHP1 including an IGBT formed therein and the semiconductor chip DCHP1 including a diode formed therein are disposed adjacent to each other via the solder S1, respectively. Then, over the semiconductor chip CHP1 and the semiconductor chip DCHP1, the clip CLP is mounted via the solder S2. Herein, the clip CLP has the shape in a structure (convex shape) in which the region of the clip CLP located between the semiconductor chip CHP1 and the semiconductor chip DCHP1 protrudes upwardly above the regions of the clip CLP in contact with the semiconductor chip CHP1 and the semiconductor chip DCHP1. In other words, the position of the region (chip-to-chip region) of the clip CLP located between the semiconductor chip CHP1 and the semiconductor chip DCHP1 is more spaced apart from the heat spreader HS than the position of the region (contact region) of the clip CLP in contact with the semiconductor chip CHP1 or the semiconductor chip DCHP1. As a result, excess solder S2 is absorbed into the convex shape of the clip CLP. Therefore, for example, the following can be prevented: the excess solder S2 runs along the side surface of the semiconductor chip CHP1 to be connected with the solder S1 formed at the part underlying the semiconductor chip CHP1.

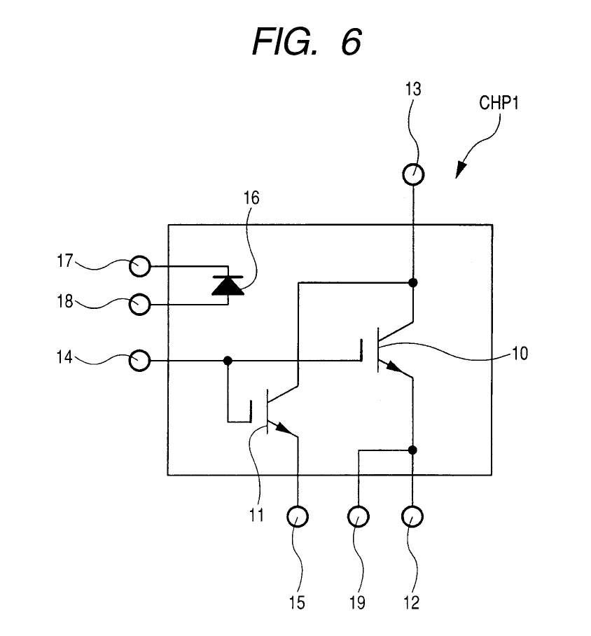

Subsequently, by showing the circuit configuration of the elements formed in the semiconductor chip CHP1, respective functions of the signal electrodes SE disposed in the single package PAC will be described. FIG. 6 is a circuit diagram showing one example of a circuit formed in the semiconductor chip CHP1. As shown in FIG. 6, in the semiconductor chip CHP1, an IGBT 10, a detecting IGBT 11, and a temperature detecting diode 16 are formed. The IGBT 10 is a main IGBT, and is used for driving of the three-phase motor 1 shown in FIG. 1. In the IGBT 10, an emitter electrode 12, a collector electrode 13, and a gate electrode 14 are formed. The gate electrode 14 is coupled to the bonding pad formed over the top surface of the semiconductor chip CHP1 through an internal wire. As shown in FIG. 4, the bonding pad is coupled to the external coupling gate electrode GE, so that the gate electrode 14 of the IGBT 10 is coupled to the external coupling gate electrode GE. The external coupling gate electrode GE is coupled to the control circuit 3 shown in FIG. 1. A signal from the control circuit 3 is applied through the external coupling gate electrode GE to the gate electrode 14 of the IGBT 10. This allows the control of the IGBT 10 from the control circuit 3.

The detecting IGBT 11 is provided in order to detect the electric current flowing between collector and emitter of the IGBT 10. Namely, the detecting IGBT 11 is provided as an inverter circuit in order to detect the electric current flowing between collector and emitter of the IGBT 10 for protecting the IGBT 10. The detecting IGBT 11 is coupled to the same collector electrode 13 and gate electrode 14 as those of the IGBT 10, and has a sense emitter electrode 15. The sense emitter electrode 15 is coupled through an internal wire to a bonding pad formed over the top surface of the semiconductor chip CHP1. The bonding pad is coupled to the current detecting electrode IE shown in FIG. 4. Therefore, eventually, the sense emitter electrode 15 of the detecting IGBT 11 is coupled to the current detecting electrode IE. Then, the current detecting electrode IE is coupled to a current detecting circuit disposed outside the single package PAC. The current detecting circuit detects the collector-emitter current of the IGBT 10 based on the output from the sense emitter electrode 15 of the detecting IGBT 11. Thus, when an overcurrent flows therethrough, the gate signal to be applied to the gate electrode 14 of the IGBT 10 is blocked. As a result, the IGBT 10 is protected.

The temperature detecting diode 16 is provided in order to detect the temperature of the IGBT 10. Namely, the voltage of the temperature detecting diode 16 varies according to the temperature of the IGBT 10. As a result, the temperature of the IGBT 10 is detected. The temperature detecting diode 16 includes a pn junction formed by introducing impurities of a different conductivity type into polysilicon, and has a cathode electrode 17 and an anode electrode 18. The cathode electrode 17 is coupled through an internal wire to a bonding pad formed over the top surface of the semiconductor chip CHP1. Similarly, the anode electrode 18 is coupled through an internal wire to a bonding pad formed over the top surface of the semiconductor chip CHP1. Therefore, the cathode electrode 17 of the temperature detecting diode 16 is coupled through the bonding pad to the temperature detecting electrode TE1 shown in FIG. 4. The anode electrode 18 of the temperature detecting diode 16 is coupled through the bonding pad to the temperature detecting electrode TE2 shown in FIG. 4. The temperature detecting electrodes TE1 and TE2 are coupled to the temperature detecting circuit provided outside the single package PAC. The temperature detecting circuit indirectly detects the temperature of the IGBT 10 based on the output between the temperature detecting electrodes TE1 and TE2 coupled to the cathode electrode 17 and the anode electrode 18 of the temperature detecting diode 16, respectively. Thus, when the detected temperature is equal to, or higher than a given temperature, the gate signal to be applied to the gate electrode 14 of the IGBT 10 is blocked. As a result, the IGBT 10 is protected.

Then, from the emitter electrode 12 of the IGBT 10, a common emitter electrode 19 which is another external extends. The common emitter electrode 19 is coupled through an internal wire to a bonding pad formed over the top surface of the semiconductor chip CHP1. The bonding pad is coupled to the Kelvin detecting electrode KE1 shown in FIG. 4. Therefore, eventually, the common emitter electrode 19 is coupled to the Kelvin detecting electrode KE1. The Kelvin detecting electrode KE1 is coupled to a Kelvin detecting circuit provided outside the single package PAC. The Kelvin detecting circuit is provided for the purpose of canceling the wiring resistance in order to prevent the electric potential of the IGBT 10 from becoming unstable by the wires or the like. Namely, based on the output from the common emitter electrode 19 having the same electric potential as that of the emitter electrode 12, the wiring resistance of the emitter electrode 12 itself is cancelled.

Similarly, as shown in FIG. 4, there is provided a Kelvin detecting electrode KE2 branching from the collector electrode of the IGBT. The Kelvin detecting electrode KE2 is coupled to the Kelvin detecting circuit provided outside the single package PAC. The Kelvin detecting circuit is also provided for the purpose of canceling the wiring resistance in order to prevent the electric potential of the IGBT 10 from becoming unstable by the wires or the like. Namely, based on the output from the Kelvin detecting electrode KE2 having the same electric potential as that of the collector electrode 13, the wiring resistance of the collector electrode 13 itself is cancelled.

Thus, according to the single package PAC in Embodiment 1, coupling can be established with the current detecting circuit, the temperature detecting circuit, and the Kelvin detecting circuit. This can improve the operation reliability of the IGBT 10 included in the single package PAC.

The single package PAC in Embodiment 1 is configured as described above. In general, the thus formed single package PAC is shipped as a product to, for example, an automaker (customer) manufacturing a hybrid car using a three-phase motor. In this case, the single package PAC shipped as a product is to be mounted in a car on the part of the customer. However, for one three-phase motor, six single packages PAC are required to be mounted. This unfavorably results in an increase in number of working steps on the part of the customer, and an increase in material cost for mounting the packages. These problems have been pointed out by the customer. In other words, although the shipped single packages are mounted, for example, on the part of the customer, the working step of mounting six single packages PAC for one three-phase motor is complicated. Further, with the single package PAC, as shown in FIGS. 2 and 3, the heat spreader HS is exposed from the back surface of the sealing body MS. This requires preparation of an insulation sheet or the like on the part of the customer in order to ensure the insulation properties between the exposed heat spreader HS and the mounting board. This results in an increase in mounting cost on the part of the customer. This problem has been pointed out. In other words, when the single package PAC obtained by integrating one IGBT and one diode into one package is supplied to a customer (automaker), the mounting burden on the part of the customer unfavorably increases.

Thus, in Embodiment 1, not the single package PAC, but a composite package obtained by further improving the single package PAC is formed. The composite package is supplied to a customer, which reduces the mounting burden on the part of the customer. Below, the configuration of the improved composite package will be described by reference to the accompanying drawings.

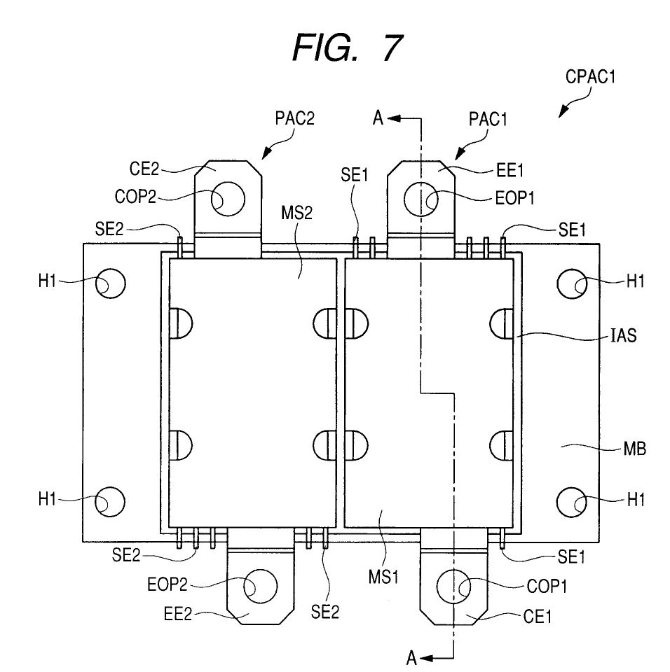

FIG. 7 is a plan view showing a configuration of a composite package CPAC1 in Embodiment 1. In FIG. 7, the composite package CPAC1 in Embodiment 1 has a metal board MB in the shape of a rectangle. Over the metal board MB, an insulation adhesion sheet IAS is formed. Then, over the insulation adhesion sheet IAS, the single package PAC1 and the single package PAC2 are mounted.

The metal board MB is formed of a material with a good thermal conductivity such as an aluminum board or a copper board. In a region outside the region in which the single package PAC1 and the single package PAC2 are mounted out of the region of the metal board MB, metal board fixing screw holes H1 are formed. The metal board fixing screw holes H1 are formed in the four corners of the metal board MB in the shape of a rectangle.

The insulation adhesion sheet IAS formed over the metal board MB includes, for example, a thermosetting resin. Specifically, the insulation adhesion sheet IAS is in a structure in which a base resin including a silicone resin or an epoxy resin is filled with a filler including ceramics such as aluminum oxide (Al₂O₃) or boron nitride or glass cloth.

The single package PAC1 and the single package PAC2 have the structure described by reference to FIGS. 2 to 5. Specifically, as shown in FIG. 7, in the central part of the single package PAC1, a sealing body MS1 in the shape of generally a rectangle in plan view is formed. At the bottom of the sealing body MS1, there are provided the external coupling collector electrode CE1 and some of the signal electrodes SE1. Then, at the top of the sealing body MS1 opposite to the bottom thereof at which the external coupling collector electrode CE1 is formed, there are formed the external coupling emitter electrode EE1 and others of the signal electrodes SE1. Then, in the external coupling collector electrode CE1, a screw opening COP1 is formed. In the external coupling emitter electrode EE1, a screw opening EOP1 is formed.

Similarly, in the central part of the single package PAC2, a sealing body MS2 in the shape of generally a rectangle in plan view is formed. At the top of the sealing body MS2, there are provided the external coupling collector electrode CE2 and some of the signal electrodes SE2. Then, at the bottom of the sealing body MS2 opposite to the top thereof at which the external coupling collector electrode CE2 is formed, there are formed the external coupling emitter electrode EE2 and others of the signal electrodes SE2. Then, in the external coupling collector electrode CE2, a screw opening COP2 is formed. In the external coupling emitter electrode EE2, a screw opening EOP2 is formed.

The thus formed composite package CPAC1 has a feature in that over the metal board MB, the single package PAC1 and the single package PAC2 are mounted together to form one composite package CPAC1. As a result, as compared with the case where six single packages are mounted, the number of packages to be mounted becomes smaller in the case where three composite packages CPAC1 are mounted. This can reduce the mounting burden on the part of the customer. Namely, when the single packages are mounted on the part of a customer, one three-phase motor requires mounting of six single packages therein. However, when the composite packages CPAC1 are mounted on the part of a customer, one three-phase motor requires mounting of only three composite packages CPAC1. Therefore, by supplying the composite packages CPAC1 to a customer, it is possible to obtain an effect of allowing a large reduction of the mounting burden on the part of the customer.

Further, the composite package CPAC1 includes the single package PAC1 and the single package PAC2 which have been previously determined as good products. For this reason, the composite package CPAC1 has a very low risk of becoming defective (malfunctioning). In other words, a composite package has such a structure that a plurality of semiconductor chips including IGBTs formed therein (IGBT chips) and semiconductor chips including diodes formed therein (diode chips) are integrated into one package. For such a composite package, for example, when one chip is defective, or when defective assembly occurs even at one site, the whole composite package becomes defective. This results in a situation in which all of good chips and other members must be disposed of. This incurs a reduction of the yield of the composite packages, leading to an increase in cost. Accordingly, as described above, by combining the single packages, and forming a composite package, it is possible to implement the improvement of the yield of the composite packages, and cost reduction thereof.

The composite package CPAC1 in Embodiment 1 is mounted in the following manner. Into the metal board fixing screw holes H1 provided in the four corners of the metal board MB, metal board fixing screws are inserted, for engagement with, for example, the housing cover of a motor. This means that, when the composite package CPAC1 is mounted on the part of a customer, it is not necessary to press the top surface (package body surface) of the composite package CPAC1 with press-down fittings. For this reason, it is possible to prevent: breakage of the single package PAC1 or the single package PAC2 mounted in the composite package CPAC1 due to pressing of the press-down fittings thereagainst; breakage of the semiconductor chips mounted inside the single packages PAC1 and PAC2 due to a pressing force thereon; and the like. Further, mounting of the composite package CPAC1 does not require press-down fittings, and the like. This means that the mounting cost can be reduced on the part of the customer. Namely, with the composite package CPAC1 in Embodiment 1, only by inserting the metal board fixing screws into the metal board fixing screw holes H1 provided in the four corners of the metal board MB, it is possible to mount the composite package CPAC1. Accordingly, all that must be prepared on the part of a customer are metal board fixing screws. Other press-down fittings, and the like are not required to be prepared. Therefore, the mounting cost can be reduced.

Further, the composite package CPAC1 in Embodiment 1 has a feature in that the direction of mounting of the single package PAC1 mounted over the metal board MB is opposite to the direction of mounting of the single package PAC2. In other words, as shown in FIG. 7, in the composite package CPAC1 in Embodiment 1, the single package PAC1 and the single package PAC2 are disposed over the insulation adhesion sheet IAS such that the external coupling emitter electrode EE1 protruding from the sealing body MS1 and the external coupling collector electrode CE2 protruding from the sealing body MS2 are disposed adjacent to each other on the side of the same side of the metal board MB. This can reduce the mounting burden on the part of a customer.

For example, the single package PAC1 mounted in the composite package CPAC1 is a package including the IGBT 4 and the diode 5 sealed therein to be coupled between the power supply potential (Vcc) and the three-phase motor shown in FIG. 1. On the other hand, the single package PAC2 mounted in the composite package CPAC1 is a package including the IGBT 4 and the diode 5 sealed therein to be coupled between the ground potential (GND) and the three-phase motor shown in FIG. 1. The single package PAC1 and the single package PAC2 mounted in the composite package CPAC1 are configured to be, as described above, the package to be coupled between the power supply potential (Vcc) and the three-phase motor, and the package to be coupled between the ground potential (GND) and the three-phase motor, respectively. As a result, the three composite packages CPAC1 having the same configuration can form the power semiconductor device 2 shown in FIG. 1. In this case, as indicated from FIG. 1, the emitter electrode of the IGBT 4 coupled between the power supply potential (Vcc) and the three-phase motor is coupled with the collector electrode of the IGBT 4 coupled between the ground potential (GND) and the three-phase motor. This means that, in the composite package CPAC1 shown in FIG. 7, the external coupling emitter electrode EE1 of the single package PAC1 is coupled with the external coupling collector electrode CE2 of the single package PAC2. Therefore, the single package PAC1 and the single package PAC2 are disposed such that the external coupling emitter electrode EE1 of the single package PAC1 and the external coupling collector electrode CE2 of the single package PAC2 are disposed on the side of the same side of the metal board MB. As a result, in mounting on the part of a customer, it is possible to readily establish a coupling between the external coupling emitter electrode EE1 of the single package PAC1 and the external coupling collector electrode CE2 of the single package PAC2. In other words, in the composite package CPAC1 in Embodiment 1, the single package PAC1 and the single package PAC2 are disposed such that the direction of mounting of the single package PAC1 mounted over the metal board MB is opposite to the direction of mounting of the single package PAC2. This advantageously facilitates mounting layout on the part of a customer, and facilitates wire coupling between the single package PAC1 and the single package PAC2.

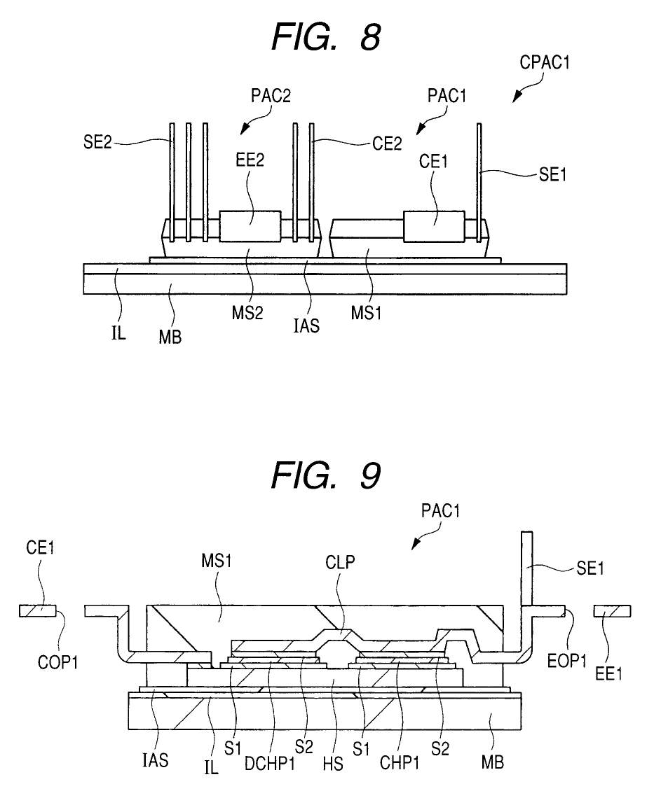

Subsequently, further advantages of the composite package CPAC1 in Embodiment 1 will be described. FIG. 8 is a view of the composite package CPAC1 in Embodiment 1 as seen from the side surface. In FIG. 8, over the surface of the metal board MB, an insulation layer IL is formed. Over the insulation layer IL, an insulation adhesion sheet IAS is formed. Then, over the insulation adhesion sheet IAS, the single package PAC1 and the single package PAC2 are mounted. FIG. 9 is a cross-sectional view cut along line A-A of FIG. 7. As also indicated in FIG. 9, over the metal board MB, the insulation layer IL is formed. Over the insulation layer IL, the insulation adhesion sheet IAS is formed. Then, over the insulation adhesion sheet IAS, the single package PAC1 is mounted. Specifically, over the insulation adhesion sheet IAS, the heat spreader HS exposed from the bottom surface of the sealing body MS1 is mounted. The heat spreader HS is coupled with the external coupling collector electrode CE1 including the screw opening COP1 formed therein. Further, over the heat spreader HS, the semiconductor chip DCHP1 and the semiconductor chip CHP1 are mounted via the solder S1. Over the top surface of the semiconductor chip DCHP1 and the top surface of the semiconductor chip CHP1, the clip CLP is disposed via the solder S2. The clip CLP is coupled with the external coupling emitter electrode EE1 including the screw opening EOP1 formed therein.

Thus, in the composite package CPAC1 in Embodiment 1, with the insulation layer of the two layers of the insulation layer IL formed over the surface of the metal board MB, and the insulation adhesion sheet IAS formed over the insulation layer IL, the single packages PAC1 and PAC2 and the metal board MB are insulated from each other. For this reason, it is possible to improve the insulation reliability between the single package PAC1 (heat spreader HS) and the metal board MB, and between the single package PAC2 (heat spreader HS) and the metal board MB. Then, in the composite package CPAC1 in Embodiment 1, the back surface of the single package PAC1, and the back surface of the single package PAC2 are insulated by the insulation adhesion sheet IAS and the insulation layer IL. This eliminates the necessity of insulating the back surface of the single package PAC1, and the back surface of the single package PAC2 in the mounting step on the part of a customer. For this reason, it is possible to omit the preparation of the insulating material, and mounting of the insulating material on the part of the customer. This means that reduction of the mounting cost and simplification of the mounting step on the part of the customer can be implemented.

Further, in the composite package CPAC1 in Embodiment 1, the single packages PAC1 and PAC2 and the insulation adhesion sheet IAS are bonded to each other. Therefore, the heat generated from the single package PAC1 or the single package PAC2 is dissipated toward the insulation adhesion sheet IAS with efficiency. In other words, in Embodiment 1, the single packages PAC1 and PAC2 and the insulation adhesion sheet IAS are bonded to each other. This enables the reduction of the thermal contact resistance between the single packages PAC1 and PAC2 and the insulation adhesion sheet IAS. As a result, in the composite package CPAC1 in Embodiment 1, the heat generated in the single packages PAC1 and PAC2 can be dissipated to the outside with efficiency, which can improve the operation reliability of the composite package CPAC1.

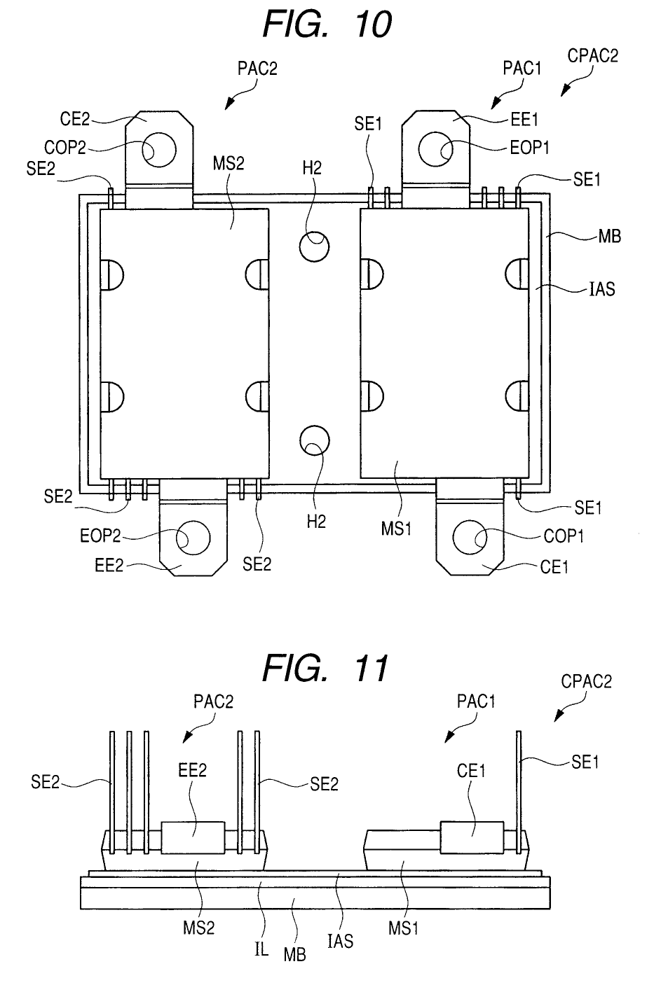

The composite package CPAC1 in Embodiment 1 is configured as described above. Below, a description will be given to the configuration of a composite package CPAC2 which is a modified example thereof. FIG. 10 is a plan view showing the configuration of the composite package CPAC2 which is a modified example thereof. As shown in FIG. 10, the composite package CPAC2 in the present modified example has the metal board MB in the shape of a rectangle. Over the metal board MB, the insulation adhesion sheet IAS is formed. Then, over the insulation adhesion sheet IAS, the single package PAC1 and the single package PAC2 are mounted. Whereas, FIG. 11 is a view of the composite package CPAC2 of the present modified example as seen from the side surface. As indicated from FIG. 11, over the surface of the metal board MB, the insulation layer IL is formed. Over the insulation layer IL, the insulation adhesion sheet IAS is formed. Then, over the insulation adhesion sheet IAS, the single package PAC1 and the single package PAC2 are mounted.

Herein, the composite package CPAC2 which is the present modified example has a feature in that, as shown in FIG. 10, in a region between the region including the single package PAC1 mounted therein and the region including the single package PAC2 mounted therein of the region of the metal board MB, the metal board fixing screw holes H2 are formed. As a result, the dimensions (size) of the composite package CPAC2 shown in FIG. 10 can be made smaller than the dimensions (size) of the composite package CPAC1 shown in FIG. 7. In other words, the composite package CPAC2 which is the present modified example can be advantageously reduced in size.

On the other hand, for the composite package CPAC1 shown in FIG. 7, in a region outside the region including the single package PAC1 and the single package PAC2 mounted therein of the region of the metal board MB, the metal board fixing screw holes H1 are formed. Then, the metal board fixing screw holes H1 are formed in the four corners of the metal board MB in the shape of a rectangle. In this case, the composite package CPAC1 shown in FIG. 7 is fixed by inserting metal board fixing screws into the metal board fixing screw holes H1 formed in the four corners of the metal board MB. Therefore, as compared with the composite package CPAC2, the composite package CPAC1 can be advantageously fixed with more reliability.

### Embodiment 2

As described up to this point, the composite package CPAC1 in Embodiment 1 and the composite package CPAC2 in the modified example respectively have different advantages, but have the same basic structure. Therefore, in Embodiment 2, by taking the composite package CPAC1 in Embodiment 1 as an example, the manufacturing method thereof will be described by reference to the accompanying drawings.

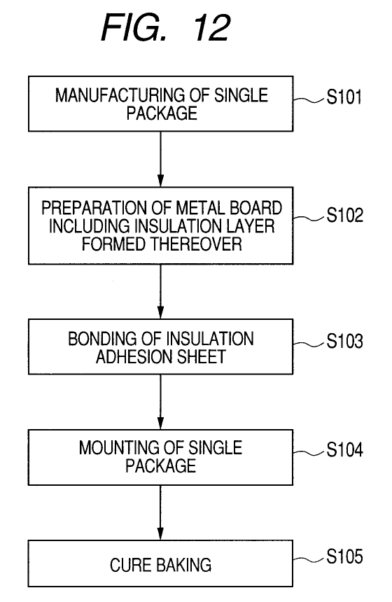

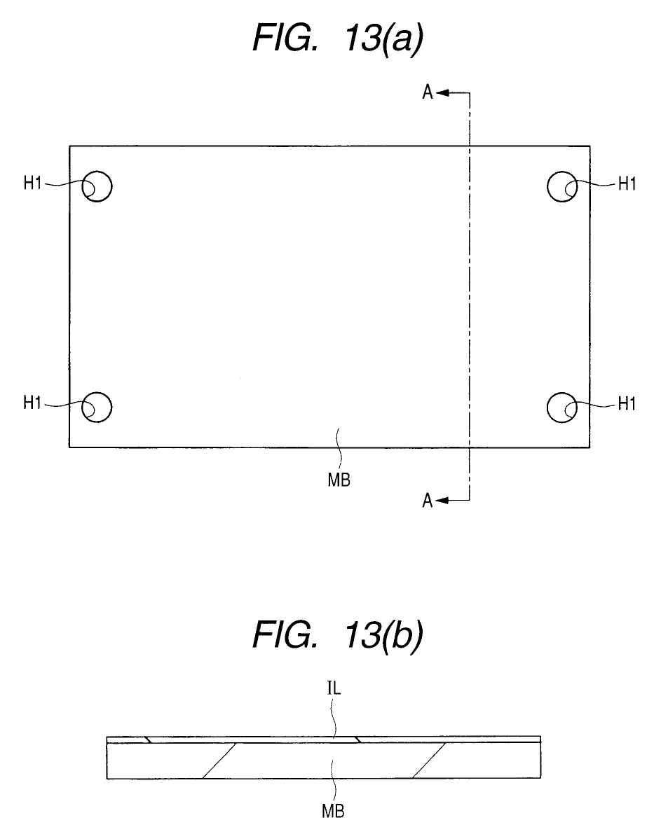

FIG. 12 is a flowchart showing a manufacturing method of the composite package CPAC1 in Embodiment 2. Whereas, FIGS. 13A to 15A are plan views each showing a manufacturing step of the composite package CPAC1. FIGS. 13B to 15B are cross-sectional views cut along lines A-A of FIGS. 13A to 15A, respectively.

First, for example, by using the technology described in Patent Literature 1, the single package PAC1 and the single package PAC2 are formed (S101 of FIG. 12).

Subsequently, as shown in FIGS. 13A and 13B, the metal board MB in the shape of a rectangle is prepared (S102 of FIG. 12). The metal board MB is formed of, for example, an aluminum board or a copper board. In the four corners of the metal board MB in the shape of a rectangle, the metal board fixing screw holes H1 are formed. Further, over the surface of the metal board MB, the insulation layer IL is formed. The insulation layer IL is formed of, for example, a material obtained by filling an epoxy resin with a filler. The thickness of the insulation layer IL is, for example, about 100 μm.

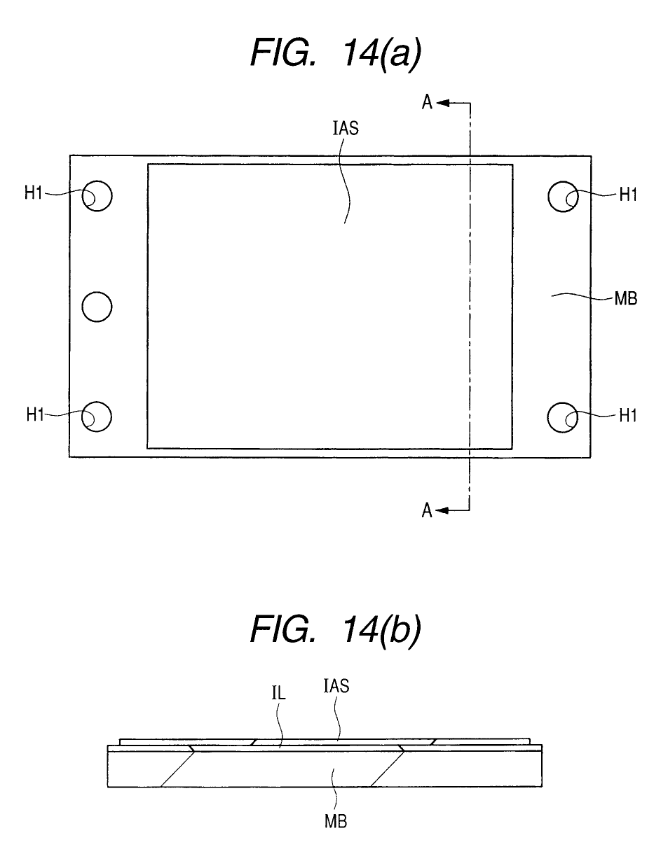

Then, as shown in FIGS. 14A and 14B, over the metal board MB including the insulation layer IL formed thereover, the insulation adhesion sheet IAS is mounted (S103 of FIG. 12). The insulation adhesion sheet IAS is formed of a thermosetting resin such as a filler-containing epoxy type adhesive. The thickness of the insulation adhesion sheet IAS is, for example, about 100 μm.

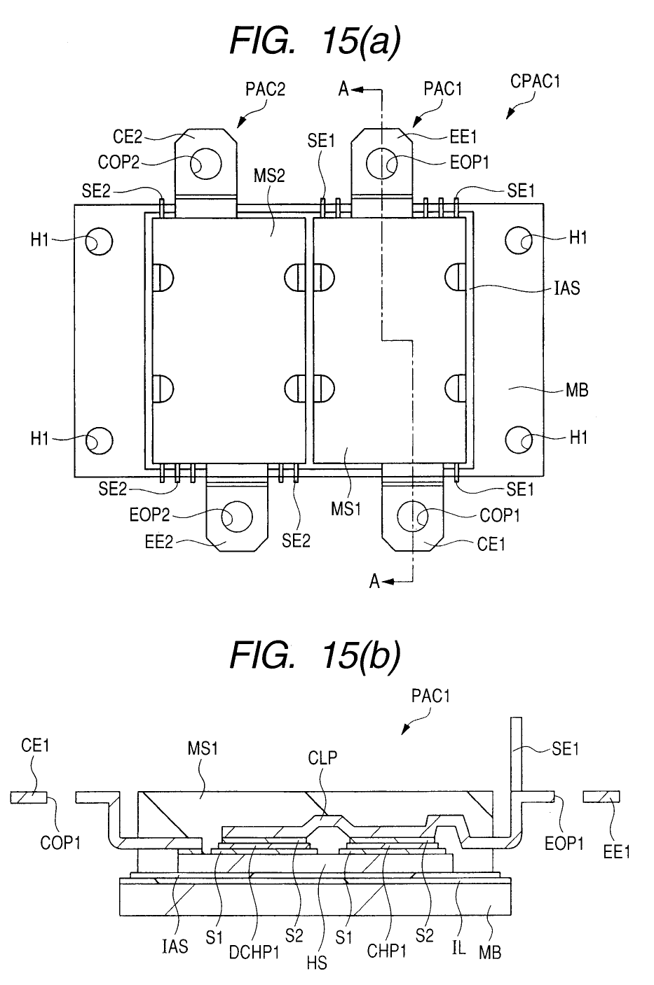

Then, as shown in FIGS. 15A and 15B, over the insulation adhesion sheet IAS, the single package PAC1 and the single package PAC2 are mounted (S104 of FIG. 12). At this step, the single package PAC1 and the single package PAC2 are mounted over the insulation adhesion sheet IAS such that the back surface of the single package PAC1 and the back surface of the single package PAC2 are in contact with the insulation adhesion sheet IAS. Whereas, the single package PAC1 and the single package PAC2 are disposed over the insulation adhesion sheet IAS such that the external coupling emitter electrode EE1 protruding from the sealing body MS1 and the external coupling collector electrode CE2 protruding from the sealing body MS2 are disposed adjacent to each other on the side of the same side of the metal board MB. Namely, the single package PAC1 and the single package PAC2 are disposed such that the direction of mounting of the single package PAC1 mounted over the metal board MB is opposite to the direction of mounting of the single package PAC2.

Subsequently, the metal board MB including the single package PAC1 and the single package PAC2 mounted thereover is subjected to a heat treatment. In other words, the insulation adhesion sheet IAS is subjected to cure baking (S105 of FIG. 12). As a result, the single package PAC1 and the single package PAC2 are bonded via the insulation adhesion sheet IAS to the metal board MB including the insulation layer IL formed thereover. In the foregoing manner, the composite package CPAC1 can be manufactured. Then, the completed composite package CPAC1 is supplied to a customer, and is mounted in the housing cover of a three-phase motor, or the like on the part of the customer.

### Embodiment 3

In Embodiment 1, a description was given to the composite package CPAC1 in which the metal board MB and the single package PAC1 (single package PAC2) were bonded to each other through the insulation adhesion sheet IAS. However, in Embodiment 3, a description will be given to a composite package CPAC3 in which the metal board MB and the single package PAC1 (single package PAC2) are fixed by a pressing plate.

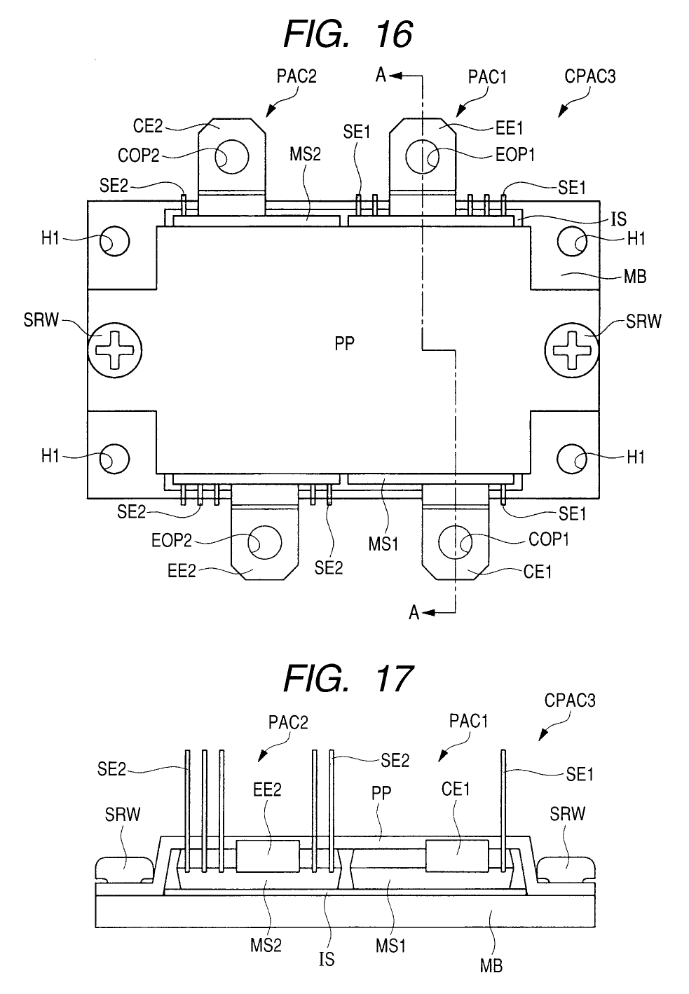

FIG. 16 is a plan view showing a configuration of the composite package CPAC3 in Embodiment 3. As shown in FIG. 16, over the metal board MB in the shape of a rectangle, an insulation sheet IS is mounted. Over the insulation sheet IS, the single package PAC1 and the single package PAC2 are mounted. Then, a pressing plate PP is formed in such a manner as to press against the top surface of the single package PAC1 and the top surface of the single package PAC2. The pressing plate PP is fixed to the metal board MB by a pressing plate fixing screw SRW. Thus, the insulation sheet IS, and the single package PAC1 and the single package PAC2, mounted over the metal board MB are fixed to the metal board MB by the pressing plate PP.

The metal board MB is formed of, for example, an aluminum board or a copper board. In the four corners thereof, the metal board fixing screw holes H1 are formed. Whereas, the insulation sheet IS is in a structure in which a base resin including a silicone resin or an epoxy resin is filled with a filler including ceramics such as aluminum oxide (Al₂O₃) or boron nitride or glass cloth. Further, the pressing plate PP is desirably formed of, for example, stainless steel from the viewpoint of ensuring the pressing strength, and is desirably formed of, for example, copper from the viewpoint of ensuring favorable thermal conductivity.

The single package PAC1 and the single package PAC2 have the structure described by reference to FIGS. 2 to 5. Specifically, as shown in FIG. 16, in the central part of the single package PAC1, the sealing body MS1 in the shape of generally a rectangle in plan view is formed. At the bottom of the sealing body MS1, there are provided the external coupling collector electrode CE1 and some of the signal electrodes SE1. Then, at the top of the sealing body MS1 opposite to the bottom thereof at which the external coupling collector electrode CE1 is formed, there are formed the external coupling emitter electrode EE1 and others of the signal electrodes SE1. Then, in the external coupling collector electrode CE1, a screw opening COP1 is formed. In the external coupling emitter electrode EE1, a screw opening EOP1 is formed.

Similarly, in the central part of the single package PAC2, the sealing body MS2 in the shape of generally a rectangle in plan view is formed. At the top of the sealing body MS2, there are provided the external coupling collector electrode CE2 and some of the signal electrodes SE2. Then, at the bottom of the sealing body MS2 opposite to the top thereof at which the external coupling collector electrode CE2 is formed, there are formed the external coupling emitter electrode EE2 and others of the signal electrodes SE2. Then, in the external coupling collector electrode CE2, a screw opening COP2 is formed. In the external coupling emitter electrode EE2, a screw opening EOP2 is formed.

FIG. 17 is a view of the composite package CPAC3 in Embodiment 3 as seen from the side surface. In FIG. 17, over the metal board MB, the insulation sheet IS is formed. Then, over the insulation sheet IS, the single package PAC1 and the single package PAC2 are mounted. At this step, in the composite package CPAC3 in Embodiment 3, the insulation sheet IS does not have adhesion properties, and is in a state simply disposed over the metal board MB. Then, the pressing plate PP is formed in such a manner as to press against the top surface of the single package PAC1 and the top surface of the single package PAC2. The pressing plate PP is fixed to the metal board MB by the pressing plate fixing screw SRW.

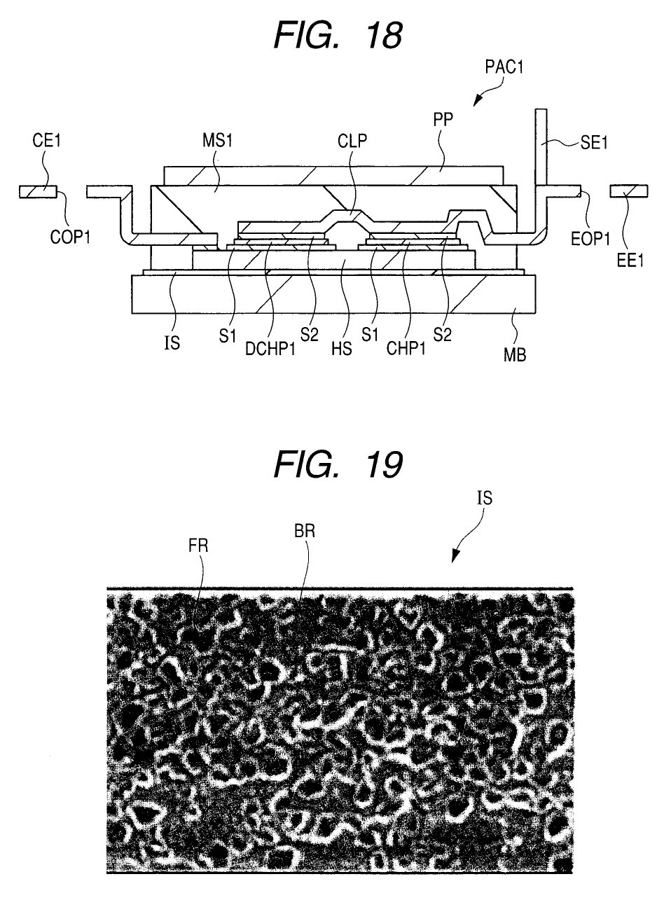

FIG. 18 is a cross-sectional view cut along line A-A of FIG. 16. As also indicated from FIG. 18, over the metal board MB, the insulation sheet IS is formed. Over the insulation sheet IS, the single package PAC1 is mounted. Specifically, over the insulation sheet IS, the heat spreader HS exposed from the bottom surface of the sealing body MS1 is mounted. The heat spreader HS is coupled with the external coupling collector electrode CE1 including the screw opening COP1 formed therein. Further, over the heat spreader HS, the semiconductor chip DCHP1 and the semiconductor chip CHP1 are mounted via the solder S1. Over the top surface of the semiconductor chip DCHP1 and the top surface of the semiconductor chip CHP1, the clip CLP is disposed via the solder S2. The clip CLP is coupled with the external coupling emitter electrode EE1 including the screw opening EOP1 formed therein. Then, over the top of the sealing body MS1, the pressing plate PP is formed.

The thus configured composite package CPAC3 has a feature in that the single package PAC1 and the single package PAC2 mounted over the metal board MB via the insulation sheet IS are pressed and fixed with the pressing plate PP. In other words, the composite package CPAC3 in Embodiment 3 does not assume a configuration in which the single package PAC1 and the single package PAC2 are bonded to the insulation adhesion sheet IAS. However, the composite package CPAC3 has a feature in that the single package PAC1 and the single package PAC2 are fixed in such a manner as to be pressed by the pressing plate PP.

As a result, the composite package CPAC3 in Embodiment 3 has an advantage of allowing replacement of the single package PAC1 (single package PAC2) which has become defective with a normal single package upon occurrence of a defect in the single package PAC1 (single package PAC2). This is for the following reason: in the composite package CPAC3 in Embodiment 3, the single package PAC1 and the single package PAC2 are not bonded to the insulation sheet IS, but are fixed thereto by the pressing plate PP. In other words, in the composite package CPAC3 in Embodiment 3, by unscrewing the pressing plate fixing screw SRW fixing the pressing plate PP, fixing by the pressing plate PP is released, which allows the single package PAC1 and the single package PAC2 to come apart (to be disassembled). Out of the single packages PAC1 (single packages PAC2) thus disassembled, a defective product is replaced with a normal product. Then, again, the single package PAC1 (single package PAC2) which is a normal product is mounted over the insulation sheet IS, and is pressed by the pressing plate PP. Then, the pressing plate PP can be fixed to the metal board MB by the pressing plate fixing screw SRW. Thus, the composite package CPAC3 in Embodiment 3 has repairability of allowing replacement of defective products with ease.

Particularly, in the composite package including a plurality of single packages mounted therein, the repairability is important. The composite package has repairability. This can avoid the situation in which when some one single package becomes defective, other good single packages are also disposed of. This also leads to the improvement of the manufacturing yield of the composite packages, and is also effective for reduction of the overall cost of the composite package.

Subsequently, the composite package CPAC3 in Embodiment 3 has a feature in that the selectivity of the insulation sheet IS can be improved. For example, when the insulation adhesion sheet IAS having adhesion properties is used as in Embodiment 1, both of the insulation properties and the adhesion properties are required thereof. For this reason, the materials for the insulation adhesion sheet IAS are limited. In contrast, the insulation sheet IS in Embodiment 3 is not required to have adhesion properties. This results in a wider range of choices for the materials. In other words, for the insulation sheet IS, the characteristics such as thermal conductivity and dielectric strength are regarded as important. However, when the materials are limited to the materials having the adhesion properties out of them, it becomes difficult to optimize the thermal conductivity, the dielectric strength, and the like. In contrast, when the adhesion properties are not required, the range of choices for the materials for the insulation sheet IS is widened. For this reason, the material for the insulation sheet IS can be selected according to the demands of various customers.

FIG. 19 is a view showing a cross-sectional structure of the insulation sheet IS. As shown in FIG. 19, the insulation sheet IS is in a structure in which a base resin BR serving as the base is filled with a filler FR. For example, the base resin BR includes epoxy resin, glass epoxy resin, or acrylic resin, and the filler FR includes ceramics such as aluminum oxide (alumina) or boron nitride, or glass cloth.

Generally, when the thermal conductivity is regarded as important, the insulation sheet IS with a high filling ratio of the filler FR is used. On the other hand, when the dielectric strength is regarded as important, the insulation sheet IS with a high content of the base resin BR is used. Therefore, the composite package CPAC3 in Embodiment 3 can be disassembled into respective structural members with ease by removing the pressing plate PP. Accordingly, the insulation sheet IS can be replaced with the one having the optimum characteristics according to the intended use. Namely, the composite package CPAC3 in Embodiment 3 can be said to be excellent in selectivity for the insulation sheet IS. For example, the following measures can be taken: for a customer who places importance on the thermal conductivity (heat radiation characteristics), the insulation sheet IS with a high filling ratio of the filler FR is used; whereas, for a customer who places importance on the dielectric strength, the insulation sheet IS with a high content of the base resin BR is used.

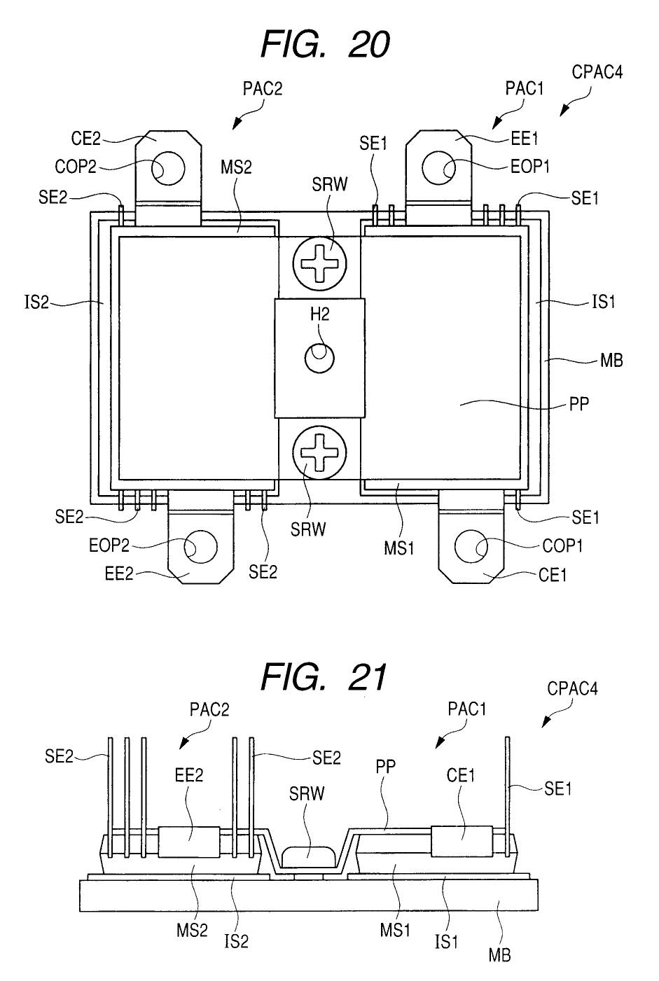

The composite package CPAC3 in Embodiment 3 is configured as described above. Below, a description will be given to the configuration of a composite package CPAC4 which is a modified example thereof. FIG. 20 is a plan view showing the configuration of the composite package CPAC4 which is a modified example thereof. As shown in FIG. 20, the composite package CPAC4 in the present modified example has the metal board MB in the shape of a rectangle. Over the metal board MB, an insulation sheet IS1 and an insulation sheet IS2 are formed. Then, over the insulation sheet IS1, the single package PAC1 is mounted, and over the insulation sheet IS2, the single package PAC2 is mounted. Then, the pressing plate PP is formed in such a manner as to press against the top surface of the single package PAC1 and the top surface of the single package PAC2. The pressing plate PP is fixed to the metal board MB by the pressing plate fixing screw SRW. Then, in the central part of the metal board MB, the metal board fixing screw holes H2 are formed.

Whereas, FIG. 21 is a view of the composite package CPAC4 in the present modified example as seen from the side surface. Also indicated from FIG. 21, over the metal board MB, the insulation sheet IS1 and the insulation sheet IS2 are formed. Over the insulation sheet IS1, the single package PAC1 is mounted, and over the insulation sheet IS2, the single package PAC2 is mounted. Further, over the single package PAC1 and the single package PAC2, the pressing plate PP is formed. The pressing plate PP is fixed to the metal board MB by the pressing plate fixing screw SRW.

Herein, the composite package CPAC4 which is the present modified example has a feature in that, as shown in FIG. 20, in a region between the region including the single package PAC1 mounted therein and the region including the single package PAC2 mounted therein of the region of the metal board MB, the metal board fixing screw holes H2 are formed, and in that the pressing plate PP is also fixed in this region. As a result, the dimensions (size) of the composite package CPAC4 shown in FIG. 20 can be made smaller than the dimensions (size) of the composite package CPAC3 shown in FIG. 16. In other words, the composite package CPAC4 which is the present modified example can be advantageously reduced in size.

On the other hand, in the composite package CPAC3 shown in FIG. 16, in a region outside the region including the single package PAC1 and the single package PAC2 mounted therein of the region of the metal board MB, the metal board fixing screw holes H1 are formed, and the pressing plate PP is also fixed in this region. Then, the metal board fixing screw holes H1 are formed in the four corners of the metal board MB in the shape of a rectangle. In this case, the composite package CPAC3 shown in FIG. 16 is fixed by inserting the metal board fixing screws into the metal board fixing screw holes H1 formed in the four corners of the metal board MB. Therefore, as compared with the composite package CPAC4, the composite package CPAC3 can be advantageously fixed with more reliability.

### Embodiment 4

As described up to this point, the composite package CPAC3 in Embodiment 3 and the composite package CPAC4 in the modified example respectively have different advantages, but have the same basic structure. Therefore, in Embodiment 4, by taking the composite package CPAC3 in Embodiment 3 as an example, the manufacturing method thereof will be described by reference to the accompanying drawings.

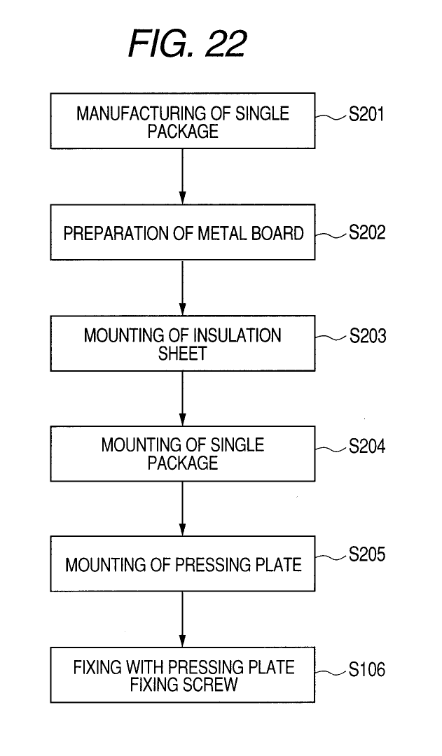

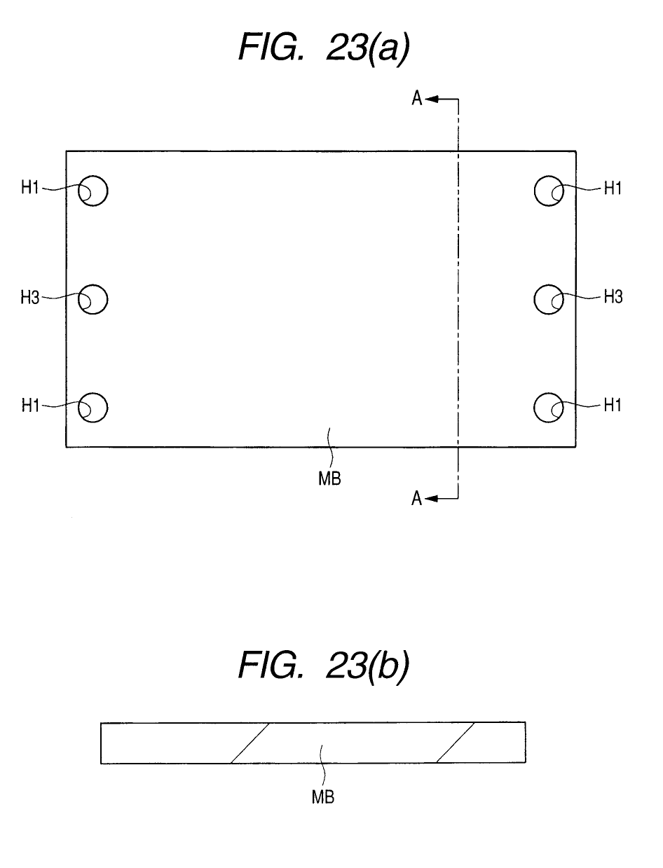

FIG. 22 is a flowchart showing a manufacturing method of the composite package CPAC3 in Embodiment 4. Whereas, FIGS. 23A to 27A are plan views each showing a manufacturing step of the composite package CPAC3. FIGS. 23B to 27B are cross-sectional views cut along lines A-A of FIGS. 23A to 27A, respectively.

First, for example, by using the technology described in Patent Literature 1, the single package PAC1 and the single package PAC2 are formed (S201 of FIG. 22).

Subsequently, as shown in FIGS. 23A and 23B, the metal board MB in the shape of a rectangle is prepared (S202 of FIG. 22). The metal board MB is formed of, for example, an aluminum board or a copper board. In the four corners of the metal board MB in the shape of a rectangle, the metal board fixing screw holes H1 are formed. Further, in the direction of the short sides of the metal board MB, pressing plate fixing screw holes H3 are formed between the metal board fixing screw holes H1.

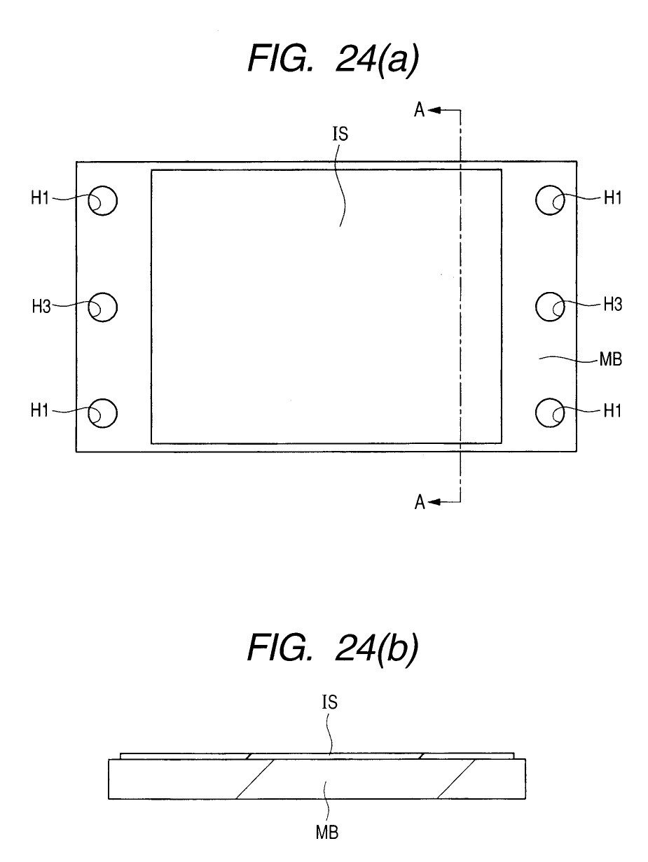

Then, as shown in FIGS. 24A and 24B, over the metal board MB, the insulation sheet IS is mounted (S203 of FIG. 22). The insulation sheet IS is formed of, for example, a filler-containing epoxy resin. The thickness of the insulation sheet IS is, for example, about 100 μm.

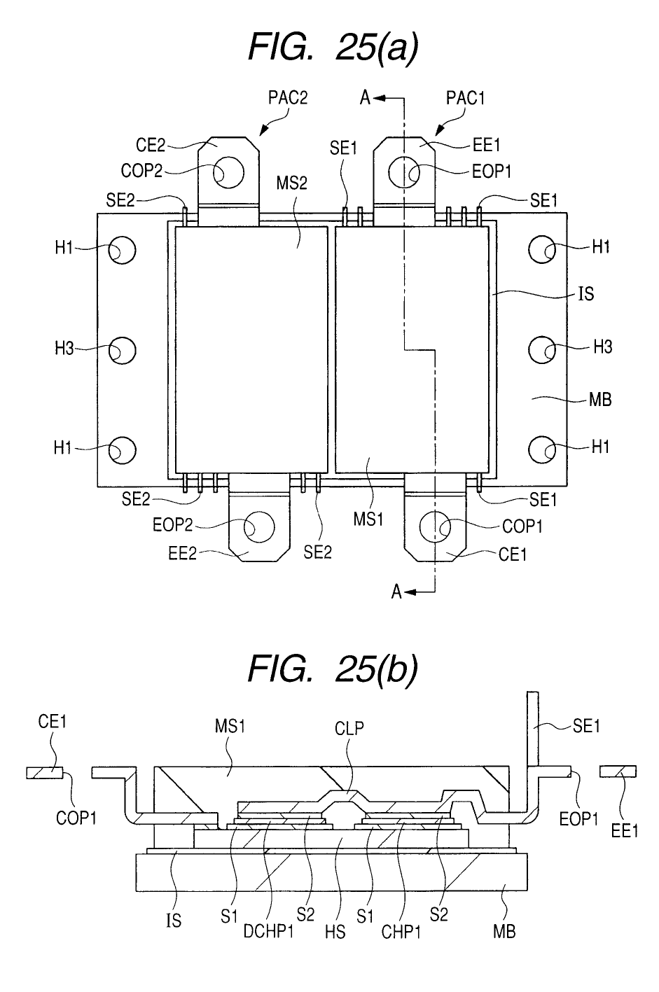

Then, as shown in FIGS. 25A and 25B, over the insulation sheet IS, the single package PAC1 and the single package PAC2 are mounted (S204 of FIG. 22). At this step, the single package PAC1 and the single package PAC2 are mounted over the insulation sheet IS such that the back surface of the single package PAC1 and the back surface of the single package PAC2 are in contact with the insulation sheet IS. Whereas, the single package PAC1 and the single package PAC2 are disposed over the insulation sheet IS such that the external coupling emitter electrode EE1 protruding from the sealing body MS1 and the external coupling collector electrode CE2 protruding from the sealing body MS2 are disposed adjacent to each other on the side of the same side of the metal board MB. Namely, the single package PAC1 and the single package PAC2 are disposed such that the direction of mounting of the single package PAC1 mounted over the metal board MB is opposite to the direction of mounting of the single package PAC2.

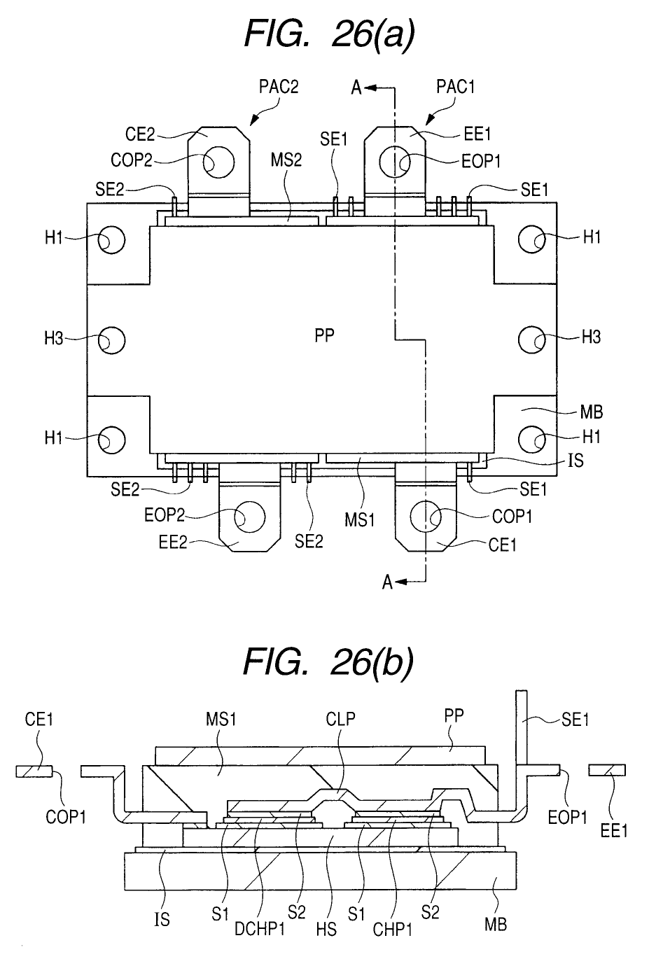

Subsequently, as shown in FIGS. 26A and 26B, the pressing plate PP is mounted in such a manner as to extend over the top of the single package PAC1 and the top of the single package PAC2 (S205 of FIG. 22). In the pressing plate PP, the pressing plate fixing screw holes H3 are formed. The pressing plate PP is disposed such that the pressing plate fixing screw holes H3 formed in the pressing plate PP overlap the pressing plate fixing screw holes H3 formed in the metal board MB in plan view, respectively.

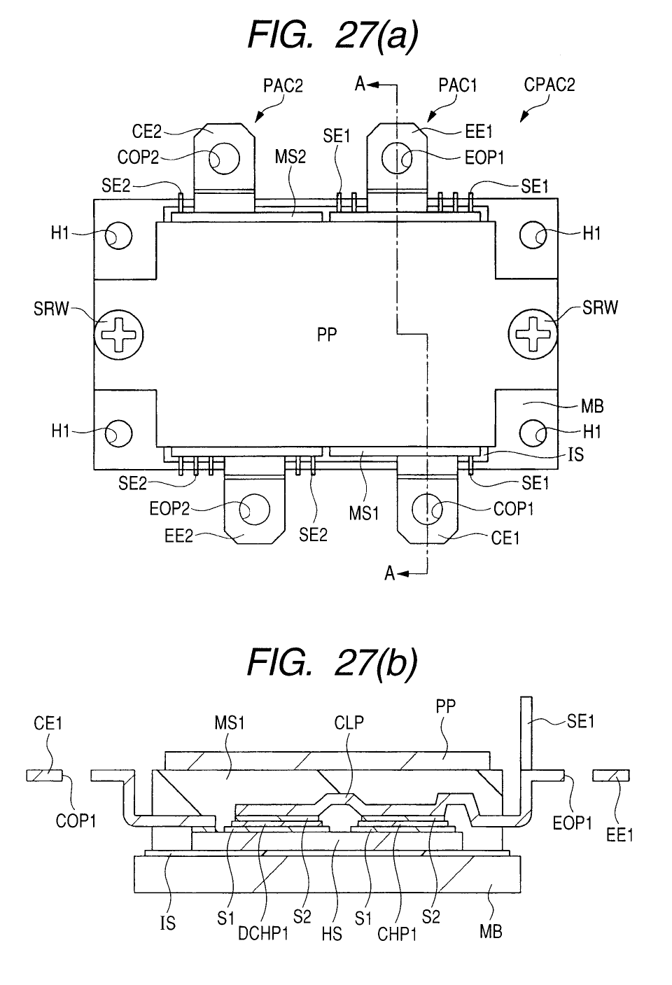

Then, as shown in FIGS. 27A and 27B, the pressing plate PP is fixed to the metal board MB by the pressing plate fixing screw SRW (S206 of FIG. 22). Namely, by inserting the pressing plate fixing screws SRW into both of the pressing plate fixing screw holes H3 formed in the pressing plate PP, and the pressing plate fixing screw holes H3 formed in the metal board MB, the pressing plate PP is fixed to the metal board MB.

In the foregoing manner, the composite package CPAC3 can be manufactured. Then, the completed composite package CPAC3 is supplied to a customer, and is mounted in the housing cover of a three-phase motor, or the like on the part of the customer.

### Embodiment 5

In Embodiment 5, as the single package PAC, there is used a double-side heat radiation type package in which the conductive member is exposed from the opposite sides of the sealing body MS, and which has been improved in heat radiation efficiency. A description will be given to a composite package CPAC5 including a plurality of the single packages PAC combined therein.

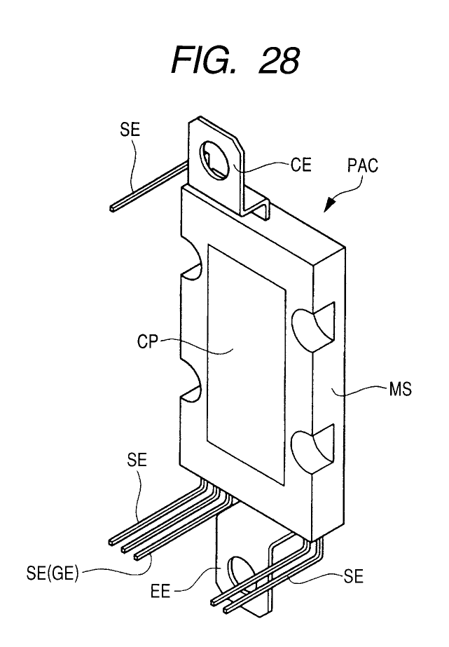

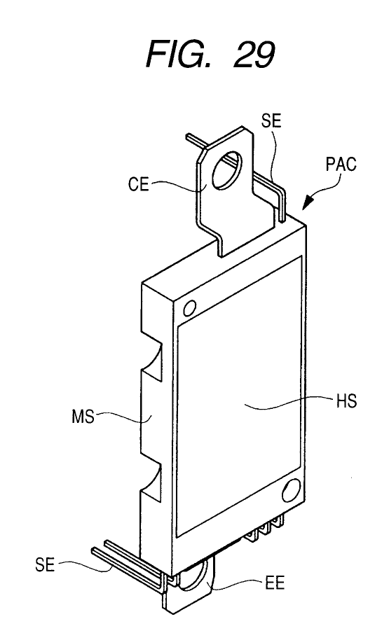

FIG. 28 is a perspective view of the single package PAC in Embodiment 5 as seen from the outer front surface side. In FIG. 28, in the central part of the single package PAC, the sealing body MS in the shape of generally a rectangle in plan view is formed. On the side of the second side of the top of the sealing body MS, there are provided the external coupling collector electrode CE and some of the signal electrodes SE. Then, on the side of the first side of the sealing body MS opposite to the second side thereof at which the external coupling collector electrode CE is formed, there are formed the external coupling emitter electrode EE and others of the signal electrodes SE. Then, in the surface of the sealing body MS, the conductive member CP is exposed. FIG. 29 is a perspective view of the single package PAC as seen from the outer back surface side. As shown in FIG. 29, on the back surface side of the sealing body MS, the heat spreader HS is exposed. Thus, the heat spreader HS is exposed from the back surface of the sealing body MS. This is in order to improve the heat radiation efficiency of the single package PAC. As described up to this point, in the single package PAC in Embodiment 5, the conductive member CP is exposed from the front surface of the sealing body MS; and the heat spreader HS is exposed from the back surface of the sealing body MS. Therefore, the single package PAC in Embodiment 5 is a double-side heat radiation type package, and a package capable of improving the heat radiation efficiency.

In Embodiment 5, using the double-side heat radiation type packages, the composite package CPAC5 is formed. Below, the configuration of the composite package CPAC5 in Embodiment 5 will be described by reference to the accompanying drawings.

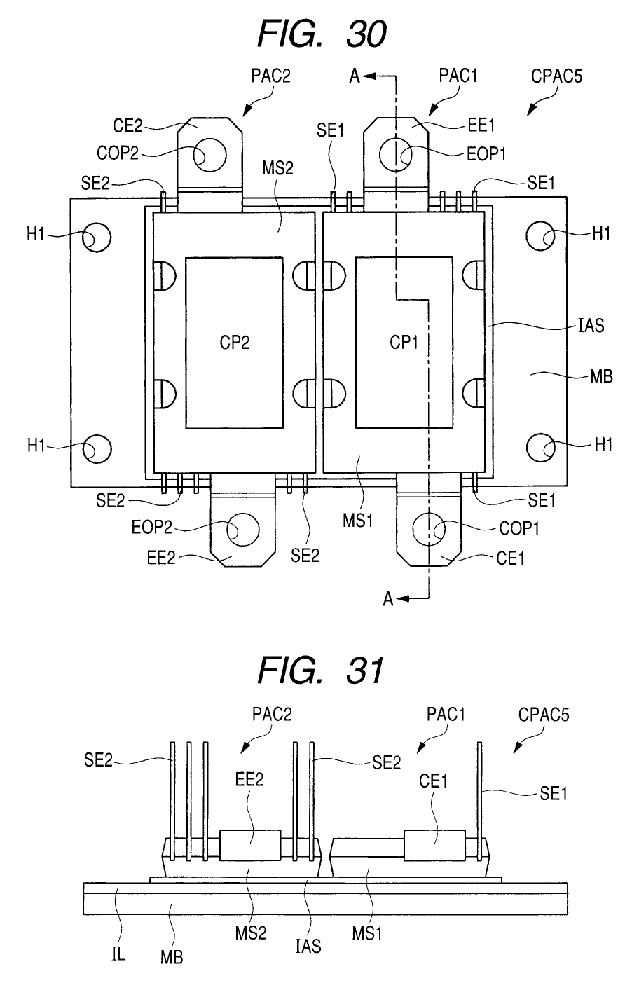

FIG. 30 is a plan view showing the configuration of the composite package CPAC5 in Embodiment 5. In FIG. 30, the composite package CPAC5 in Embodiment 5 has the metal board MB in the shape of a rectangle. Over the metal board MB, the insulation adhesion sheet IAS is formed. Then, over the insulation adhesion sheet IAS, the single package PAC1 and the single package PAC2 are mounted.

The metal board MB is formed of a material with a good thermal conductivity such as an aluminum board or a copper board. In a region outside the region in which the single package PAC1 and the single package PAC2 are mounted of the region of the metal board MB, metal board fixing screw holes H1 are formed. The metal board fixing screw holes H1 are formed in the four corners of the metal board MB in the shape of a rectangle.

The insulation adhesion sheet IAS formed over the metal board MB includes, for example, a thermosetting resin. Specifically, the insulation adhesion sheet IAS is in a structure in which a base resin including a silicone resin or an epoxy resin is filled with a filler including ceramics such as aluminum oxide (Al₂O₃) or boron nitride or glass cloth.

The single package PAC1 and the single package PAC2 have the outward appearance structure described by reference to FIGS. 28 and 29. Specifically, as shown in FIG. 30, in the central part of the single package PAC1, the sealing body MS1 in the shape of generally a rectangle in plan view is formed. At the bottom of the sealing body MS1, there are provided the external coupling collector electrode CE1 and some of the signal electrodes SE1. Then, at the top of the sealing body MS1 opposite to the bottom thereof at which the external coupling collector electrode CE1 is formed, there are formed the external coupling emitter electrode EE1 and others of the signal electrodes SE1. Then, in the external coupling collector electrode CE1, a screw opening COP1 is formed. In the external coupling emitter electrode EE1, a screw opening EOP1 is formed.

Similarly, in the central part of the single package PAC2, the sealing body MS2 in the shape of generally a rectangle in plan view is formed. At the top of the sealing body MS2, there are provided the external coupling collector electrode CE2 and some of the signal electrodes SE2. Then, at the bottom of the sealing body MS2 opposite to the top thereof at which the external coupling collector electrode CE2 is formed, there are formed the external coupling emitter electrode EE2 and others of the signal electrodes SE2. Then, in the external coupling collector electrode CE2, a screw opening COP2 is formed. In the external coupling emitter electrode EE2, a screw opening EOP2 is formed.

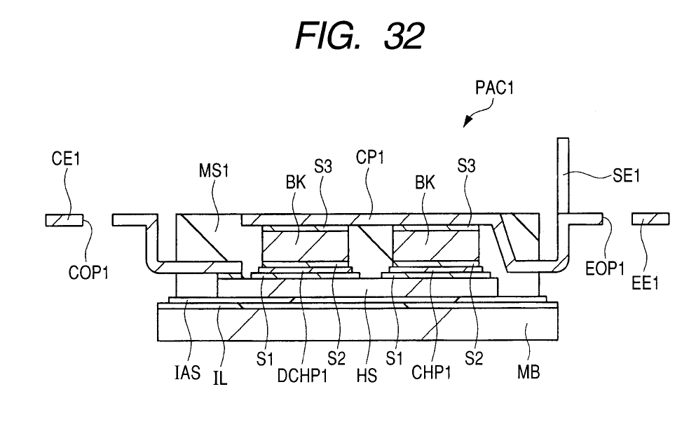

FIG. 31 is a view of the composite package CPAC5 in Embodiment 5 as seen from the side surface. In FIG. 31, over the surface of the metal board MB, an insulation layer IL is formed. Over the insulation layer IL, an insulation adhesion sheet IAS is formed. Then, over the insulation adhesion sheet IAS, the single package PAC1 and the single package PAC2 are mounted. FIG. 32 is a cross-sectional view cut along line A-A of FIG. 30. As also indicated in FIG. 32, over the metal board MB, the insulation layer IL is formed. Over the insulation layer IL, the insulation adhesion sheet IAS is formed. Then, over the insulation adhesion sheet IAS, the single package PAC1 is mounted. Specifically, over the insulation adhesion sheet IAS, the heat spreader HS exposed from the bottom surface of the sealing body MS1 is mounted. The heat spreader HS is coupled with the external coupling collector electrode CE1 including the screw opening COP1 formed therein. Further, over the heat spreader HS, the semiconductor chip DCHP1 and the semiconductor chip CHP1 are mounted via the solder S1. Over the top surface of the semiconductor chip DCHP1 and the top surface of the semiconductor chip CHP1, a copper block BK is disposed via the solder S2. Over the copper block BK, the conductive member CP1 is formed via a solder S3. The surface of the conductive member CP1 is exposed from the surface of the sealing body MS1. Then, the conductive member CP1 is coupled with the external coupling emitter electrode EE1 including the screw opening EOP1 formed therein. At this step, in FIG. 32, the conductive member CP1 is indirectly coupled with the semiconductor chip DCHP1 and the semiconductor chip CHP1 via the copper block BK. However, the following configuration is also acceptable: the conductive member CP1 is formed with a large thickness, so that the semiconductor chip DCHP1 and the semiconductor chip CHP1 are directly coupled with the conductive member CP1 via the solder S2.

In the composite package CPAC5 configured as described up to this point, at the top surface of the single package PAC1, the conductive member CP1 is exposed. At the top surface of the single package PAC2, the conductive member CP2 is exposed. Therefore, the heat generated inside the single package PAC1 is dissipated from the exposed conductive member CP1 with efficiency. The heat generated inside the single package PAC2 is dissipated from the exposed conductive member CP2 with efficiency. As a result, with the composite package CPAC5 in Embodiment 5, the heat radiation efficiency can be improved, and the stable operation can be ensured.

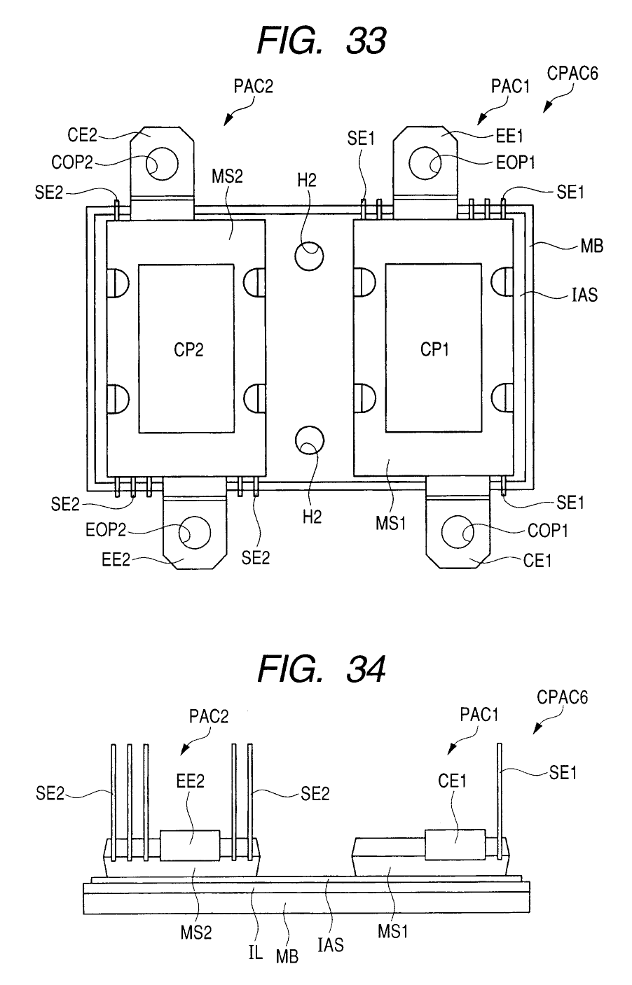

The composite package CPAC5 in Embodiment 5 is configured as described above. Below, a description will be given to the configuration of a composite package CPAC6 which is a modified example thereof. FIG. 33 is a plan view showing the configuration of the composite package CPAC6 which is the modified example. As shown in FIG. 33, the composite package CPAC6 in the present modified example has the metal board MB in the shape of a rectangle. Over the metal board MB, the insulation adhesion sheet IAS is formed. Then, over the insulation adhesion sheet IAS, the single package PAC1 and the single package PAC2 are mounted. At the surface of the single package PAC1, the conductive member CP1 is exposed. At the surface of the single package PAC2, the conductive member CP2 is exposed.

Further, FIG. 34 is a view of the composite package CPAC6 in the present modified example as seen from the side surface. As indicated from FIG. 34, over the surface of the metal board MB, the insulation layer IL is formed; and over the insulation layer IL, the insulation adhesion sheet IAS is formed. Then, over the insulation adhesion sheet IAS, the single package PAC1 and the single package PAC2 are mounted.

Herein, the composite package CPAC6 which is the present modified example has a feature in that, as shown in FIG. 33, in a region between the region including the single package PAC1 mounted therein and the region including the single package PAC2 mounted therein of the region of the metal board MB, the metal board fixing screw holes H2 are formed. As a result, the dimensions (size) of the composite package CPAC6 shown in FIG. 33 can be made smaller than the dimensions (size) of the composite package CPAC5 shown in FIG. 30. In other words, the composite package CPAC6 which is the present modified example can be advantageously reduced in size.

On the other hand, in the composite package CPAC5 shown in FIG. 30, in a region outside the region including the single package PAC1 and the single package PAC2 mounted therein of the region of the metal board MB, the metal board fixing screw holes H1 are formed. Then, the metal board fixing screw holes H1 are formed in the four corners of the metal board MB in the shape of a rectangle. In this case, the composite package CPAC5 shown in FIG. 30 is fixed by inserting the metal board fixing screws into the metal board fixing screw holes H1 formed in the four corners of the metal board MB. Therefore, the composite package CPAC5 can be advantageously fixed with reliability.

The manufacturing method of the composite package CPAC5 in Embodiment 5 is the same as that in Embodiment 2, and hence a description thereon is omitted.

### Embodiment 6

In Embodiment 6, as the single package PAC, there is used a double-side heat radiation type package in which the conductive member is exposed from the opposite sides of the sealing body MS, and which has been improved in heat radiation efficiency. A description will be given to a composite package CPAC7 including a plurality of the single packages PAC combined therein.

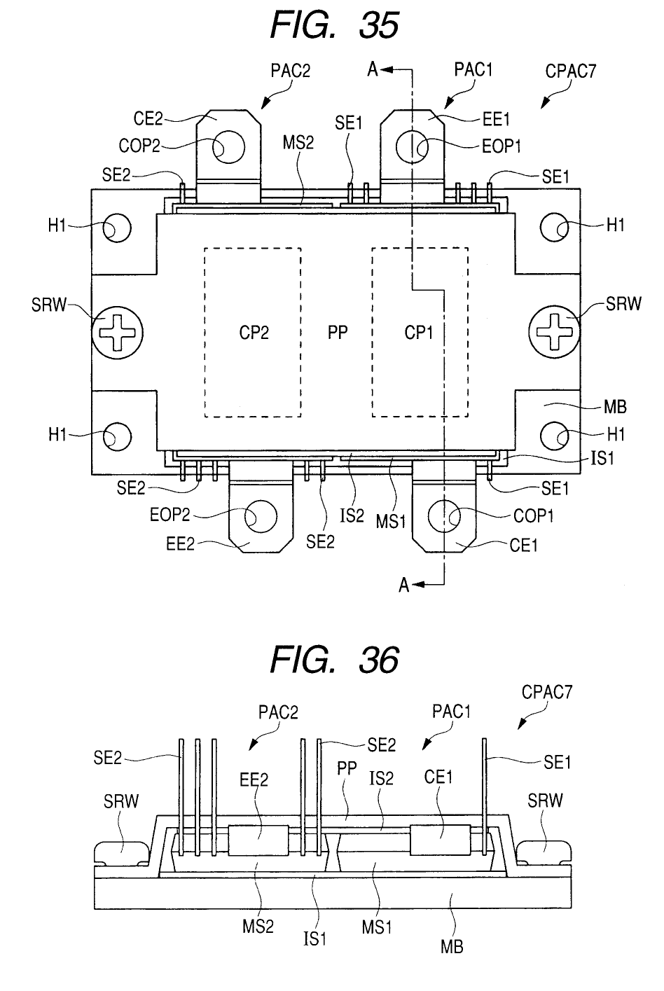

FIG. 35 is a plan view showing a configuration of the composite package CPAC7 in Embodiment 6. As shown in FIG. 35, over the metal board MB in the shape of a rectangle, the insulation sheet IS1 is mounted. Over the insulation sheet IS1, the single package PAC1 and the single package PAC2 are mounted. Then, over the top surface of the single package PAC1 and the top surface of the single package PAC2, the insulation sheet IS2 is formed. Over the insulation sheet IS2, the pressing plate PP is formed. The pressing plate PP is fixed to the metal board MB by the pressing plate fixing screws SRW. Thus, the insulation sheet IS1, the single package PAC1, the single package PAC2, and the insulation sheet IS2 mounted over the metal board MB are fixed to the metal board MB by the pressing plate PP.

The metal board MB is formed of, for example, an aluminum board or a copper board. In the four corners thereof, the metal board fixing screw holes H1 are formed. Whereas, the insulation sheet IS1 and the insulation sheet IS2 are each in a structure in which a base resin including a silicone resin or an epoxy resin is filled with a filler including ceramics such as aluminum oxide (Al₂O₃) or boron nitride or glass cloth. Further, the pressing plate PP is desirably formed of, for example, stainless steel from the viewpoint of ensuring the pressing strength, and is desirably formed of, for example, copper from the viewpoint of ensuring favorable thermal conductivity.

The single package PAC1 and the single package PAC2 have the outward appearance structure described by reference to FIGS. 28 and 29. Specifically, as shown in FIG. 35, in the central part of the single package PAC1, the sealing body MS1 in the shape of generally a rectangle in plan view is formed. At the bottom of the sealing body MS1, there are provided the external coupling collector electrode CE1 and some of the signal electrodes SE. Then, at the top of the sealing body MS1 opposite to the bottom thereof at which the external coupling collector electrode CE1 is formed, there are formed the external coupling emitter electrode EE1 and others of the signal electrodes SE1. Then, in the external coupling collector electrode CE1, a screw opening COP1 is formed. In the external coupling emitter electrode EE1, a screw opening EOP1 is formed.

Similarly, in the central part of the single package PAC2, the sealing body MS2 in the shape of generally a rectangle in plan view is formed. At the top of the sealing body MS2, there are provided the external coupling collector electrode CE2 and some of the signal electrodes SE2. Then, at the bottom of the sealing body MS2 opposite to the top thereof at which the external coupling collector electrode CE2 is formed, there are formed the external coupling emitter electrode EE2 and others of the signal electrodes SE2. Then, in the external coupling collector electrode CE2, a screw opening COP2 is formed. In the external coupling emitter electrode EE2, a screw opening EOP2 is formed.

FIG. 36 is a view of the composite package CPAC7 in Embodiment 6 as seen from the side surface. In FIG. 36, over the metal board MB, the insulation sheet IS1 is formed. Then, over the insulation sheet IS1, the single package PAC1 and the single package PAC2 are mounted. At this step, in the composite package CPAC7 in Embodiment 6, the insulation sheet IS1 does not have adhesion properties, and is in a state simply disposed over the metal board MB. Then, over the top surface of the single package PAC1 and the top surface of the single package PAC2, the insulation sheet IS2 is formed. The pressing plate PP is formed in such a manner as to press against the single package PAC1 and the single package PAC2 via the insulation sheet IS2. The pressing plate PP is fixed to the metal board MB by the pressing plate fixing screw SRW.

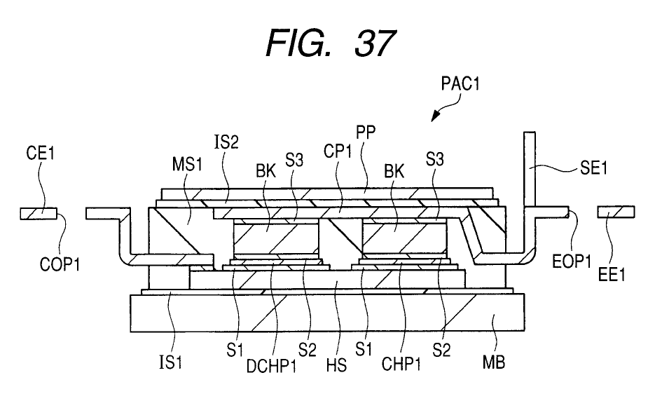

FIG. 37 is a cross-sectional view cut along line A-A of FIG. 35. As also indicated from FIG. 37, over the metal board MB, the insulation sheet IS1 is formed; and over the insulation sheet IS, the single package PAC1 is mounted. Specifically, over the insulation sheet IS1, the heat spreader HS exposed from the bottom surface of the sealing body MS1 is mounted. The heat spreader HS is coupled with the external coupling collector electrode CE1 including the screw opening COP1 formed therein.

Further, over the heat spreader HS, the semiconductor chip DCHP1 and the semiconductor chip CHP1 are mounted via the solder S1. Over the top surface of the semiconductor chip DCHP1 and the top surface of the semiconductor chip CHP1, a copper block BK is disposed via the solder S2. Over the copper block BK, the conductive member CP1 is formed via the solder S3. The surface of the conductive member CP1 is exposed from the surface of the sealing body MS1. Then, the conductive member CP1 is coupled with the external coupling emitter electrode EE1 including the screw opening EOP1 formed therein. At this step, in FIG. 37, the conductive member CP1 is indirectly coupled with the semiconductor chip DCHP1 and the semiconductor chip CHP1 via the copper block BK. However, the following configuration is also acceptable: the conductive member CP1 is formed with a large thickness, so that the semiconductor chip DCHP1 and the semiconductor chip CHP1 are directly coupled with the conductive member CP1 via the solder S2.

Further, over the surface of the sealing body MS1 from which the surface of the conductive member CP1 is exposed, the insulation sheet IS2 is formed. Over the insulation sheet IS2, the pressing plate PP is formed. Herein, a description will be given to the reason why the pressing plate PP is not directly formed over the single package PAC1 and over the single package PAC2. In Embodiment 6, at the surface of the single package PAC1, the conductive member CP1 is exposed, and at the surface of the single package PAC2, the conductive member CP2 is exposed. Therefore, when the pressing plate PP including a metal is directly mounted over the single package PAC1 and the single package PAC2, a conduction between the exposed conductive member CP1 and conductive member CP2 is established via the pressing plate PP. For this reason, in Embodiment 6, over the single package PAC1 and over the single package PAC2, the insulation sheet IS2 is formed. Over the insulation sheet IS2, the pressing plate PP is mounted. This prevents a short circuit between the conductive member CP1 and the conductive member CP2.

Incidentally, in Embodiment 6, as with the insulation sheet IS1, the insulation sheet IS2 is also improved in selectivity. Therefore, for example, for a customer who places importance on the thermal conductivity (heat radiation characteristics), the insulation sheet IS2 with a high filling ratio of the filler FR is used; whereas, for a customer who places importance on the dielectric strength, the insulation sheet IS2 with a high content of the base resin BR is used.

In the composite package CPAC7 formed as described up to this point, at the top surface of the single package PAC1, the conductive member CP1 is exposed; and at the top surface of the single package PAC2, the conductive member CP2 is exposed. Therefore, the heat generated inside the single package PAC1 is dissipated from the exposed conductive member CP1 with efficiency. The heat generated inside the single package PAC2 is dissipated from the exposed conductive member CP2 with efficiency. As a result, with the composite package CPAC7 in Embodiment 6, the heat radiation efficiency can be improved, and the stable operation can be ensured.

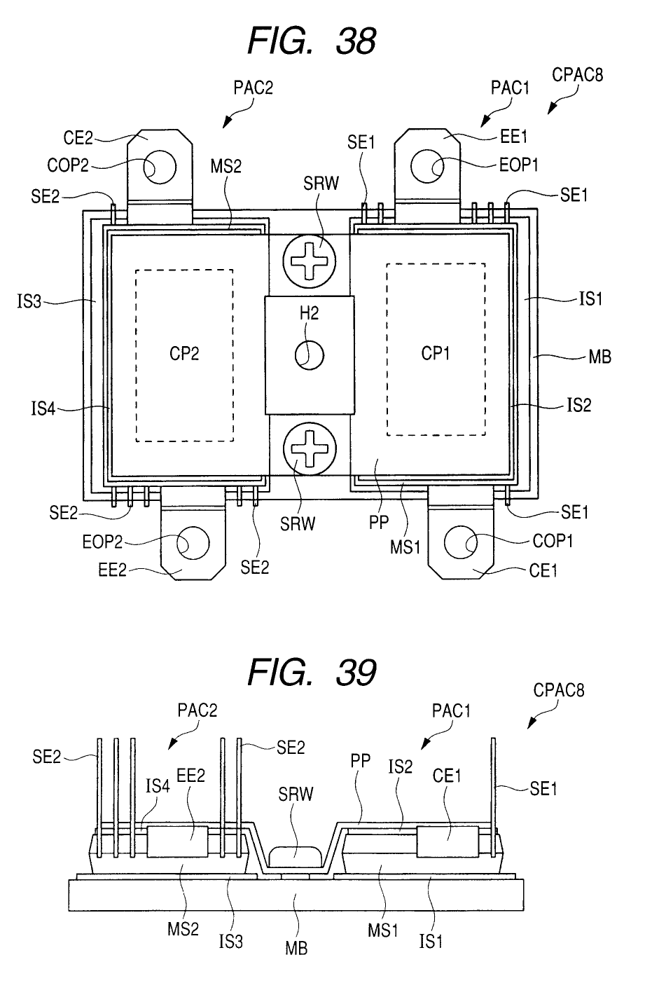

The composite package CPAC7 in Embodiment 6 is configured as described above. Below, a description will be given to the configuration of a composite package CPAC8 which is a modified example thereof. FIG. 38 is a plan view showing the configuration of the composite package CPAC8 which is a modified example thereof. As shown in FIG. 38, the composite package CPAC8 in the present modified example has the metal board MB in the shape of a rectangle. Over the metal board MB, an insulation sheet IS1 and an insulation sheet IS3 are formed. Then, over the insulation sheet IS1, the single package PAC1 is mounted, and over the insulation sheet IS3, the single package PAC2 is mounted. At the top surface of the single package PAC1, the conductive member CP1 is exposed. At the top surface of the single package PAC2, the conductive member CP2 is exposed. Then, over the top surface of the single package PAC1, an insulation sheet IS2 is formed and over the top surface of the single package PAC2, an insulation sheet IS4 is formed. Over the insulation sheet IS2 and the insulation sheet IS4, the pressing plate PP is formed in such a manner as to press against the single package PAC1 and the single package PAC2. The pressing plate PP is fixed to the metal board MB by the pressing plate fixing screws SRW. Then, in the central part of the metal board MB, the metal board fixing screw holes H2 are formed.

Whereas, FIG. 39 is a view of the composite package CPAC8 in the present modified example as seen from the side surface. Also indicated from FIG. 39, over the metal board MB, the insulation sheet IS1 and the insulation sheet IS3 are formed. Over the insulation sheet IS1, the single package PAC1 is mounted, and over the insulation sheet IS3, the single package PAC2 is mounted. Further, over the single package PAC1, the insulation sheet IS2 is formed, and over the single package PAC2, the insulation sheet IS4 is formed. Over the insulation sheet IS2 and the insulation sheet IS4, the pressing plate PP is formed. The pressing plate PP is fixed to the metal board MB by the pressing plate fixing screw SRW.

Herein, the composite package CPAC8 which is the present modified example has a feature in that, as shown in FIG. 38, in a region between the region including the single package PAC1 mounted therein and the region including the single package PAC2 mounted therein of the region of the metal board MB, the metal board fixing screw holes H2 are formed, and in that the pressing plate PP is also fixed in this region. As a result, the dimensions (size) of the composite package CPAC8 shown in FIG. 38 can be made smaller than the dimensions (size) of the composite package CPAC7 shown in FIG. 35. In other words, the composite package CPAC8 which is the present modified example can be advantageously reduced in size.

On the other hand, in the composite package CPAC7 shown in FIG. 35, in a region outside the region including the single package PAC1 and the single package PAC2 mounted therein of the region of the metal board MB, the metal board fixing screw holes H1 are formed, and the pressing plate PP is also fixed in this region. Then, the metal board fixing screw holes H1 are formed in the four corners of the metal board MB in the shape of a rectangle. In this case, the composite package CPAC7 shown in FIG. 35 is fixed by inserting the metal board fixing screws into the metal board fixing screw holes H1 formed in the four corners of the metal board MB. Therefore, the composite package CPAC7 can be advantageously fixed with reliability.

### Embodiment 7

As described up to this point, the composite package CPAC7 in Embodiment 6 and the composite package CPAC8 in the modified example respectively have different advantages, but have the same basic structure. Therefore, in Embodiment 7, by taking the composite package CPAC7 in Embodiment 6 as an example, the manufacturing method thereof will be described by reference to the accompanying drawings.

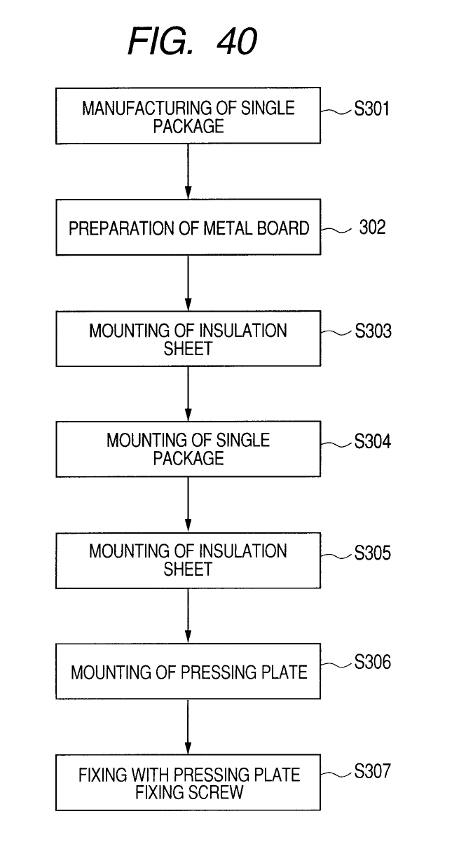

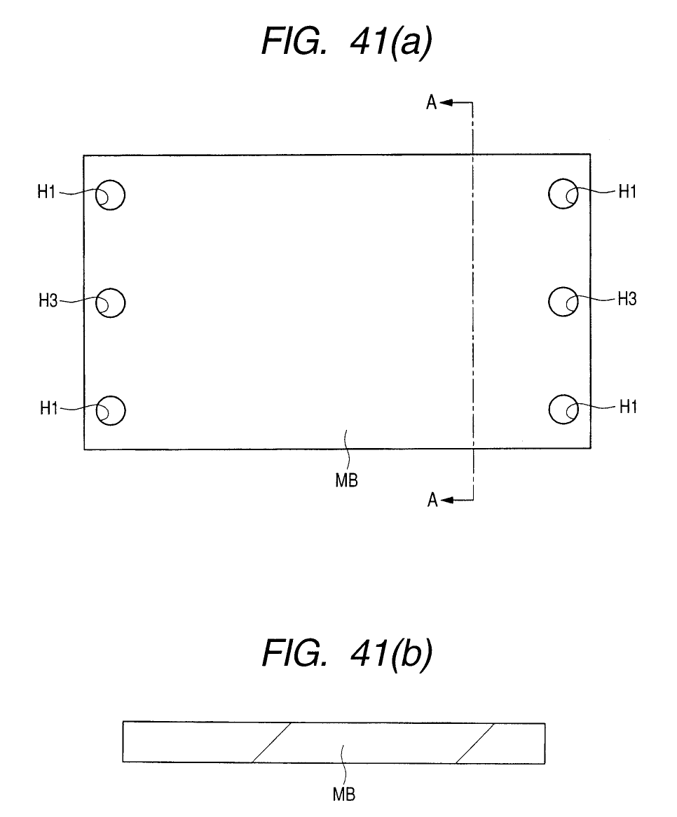

FIG. 40 is a flowchart showing a manufacturing method of the composite package CPAC7 in Embodiment 7. Whereas, FIGS. 41A to 46A are plan views each showing a manufacturing step of the composite package CPAC7. FIGS. 41B to 46B are cross-sectional views cut along lines A-A of FIGS. 41A to 46A, respectively.

First, for example, by using the technology described in Patent Literature 1, the single package PAC1 and the single package PAC2 are formed (S301 of FIG. 40).

Subsequently, as shown in FIGS. 41A and 41B, the metal board MB in the shape of a rectangle is prepared (S302 of FIG. 40). The metal board MB is formed of, for example, an aluminum board or a copper board. In the four corners of the metal board MB in the shape of a rectangle, the metal board fixing screw holes H1 are formed. Further, in the direction of the short sides of the metal board MB, pressing plate fixing screw holes H3 are formed between the metal board fixing screw holes H1.

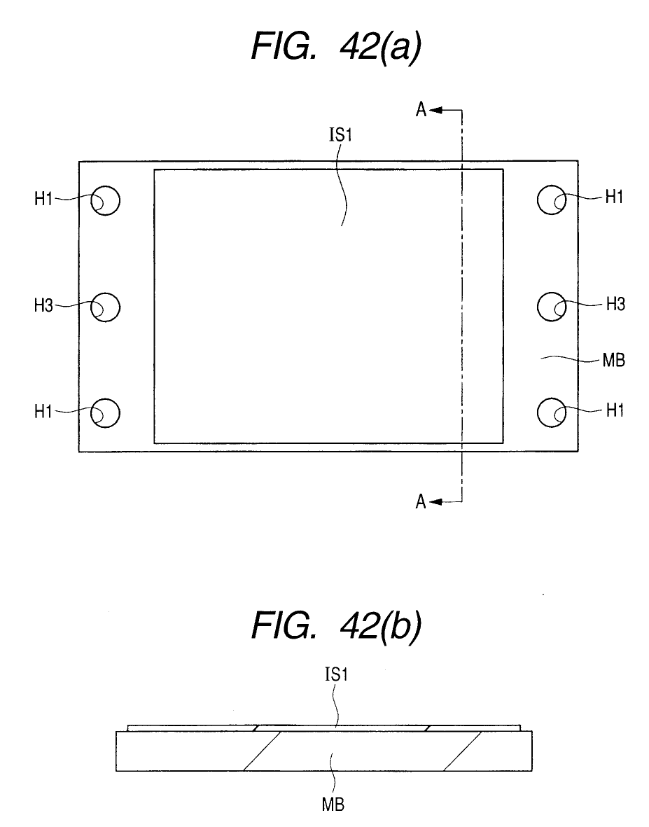

Then, as shown in FIGS. 42A and 42B, over the metal board MB, the insulation sheet IS1 is mounted (S303 of FIG. 40). The insulation sheet IS1 is formed of, for example, a filler-containing epoxy resin. The thickness of the insulation sheet IS1 is, for example, about 100 μm.

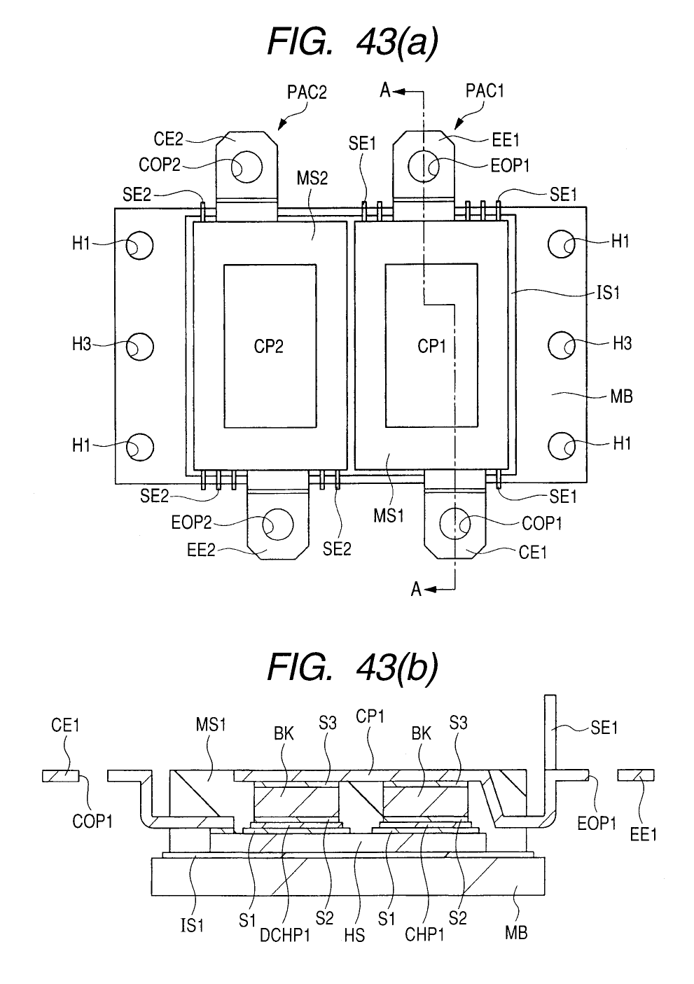

Then, as shown in FIGS. 43A and 43B, over the insulation sheet IS1, the single package PAC1 and the single package PAC2 are mounted (S304 of FIG. 40). At this step, the single package PAC1 and the single package PAC2 are mounted over the insulation sheet IS1 such that the back surface of the single package PAC1 and the back surface of the single package PAC2 are in contact with the insulation sheet IS1. Whereas, the single package PAC1 and the single package PAC2 are disposed over the insulation sheet IS1 such that the external coupling emitter electrode EE1 protruding from the sealing body MS1 and the external coupling collector electrode CE2 protruding from the sealing body MS2 are disposed adjacent to each other on the side of the same side of the metal board MB. Namely, the single package PAC1 and the single package PAC2 are disposed such that the direction of mounting of the single package PAC1 mounted over the metal board MB is opposite to the direction of mounting of the single package PAC2. Further, at the top surface of the single package PAC1, the conductive member CP1 is exposed. At the top surface of the single package PAC2, the conductive member CP2 is exposed.

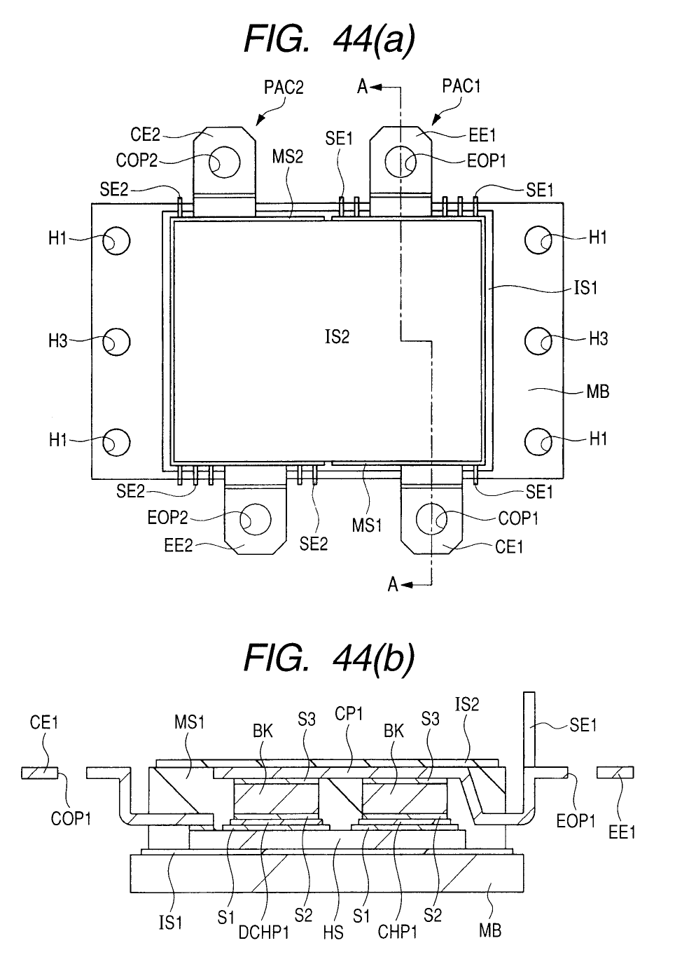

Then, as shown in FIGS. 44A and 44B, across over the single package PAC1 at which the conductive member CP1 is exposed, and over the single package PAC2 at which the conductive member CP2 is exposed, the insulation sheet IS2 is mounted (S305 of FIG. 40). The insulation sheet IS2 is formed of, for example, a filler-containing epoxy resin. The thickness of the insulation sheet IS2 is, for example, 100 μm.

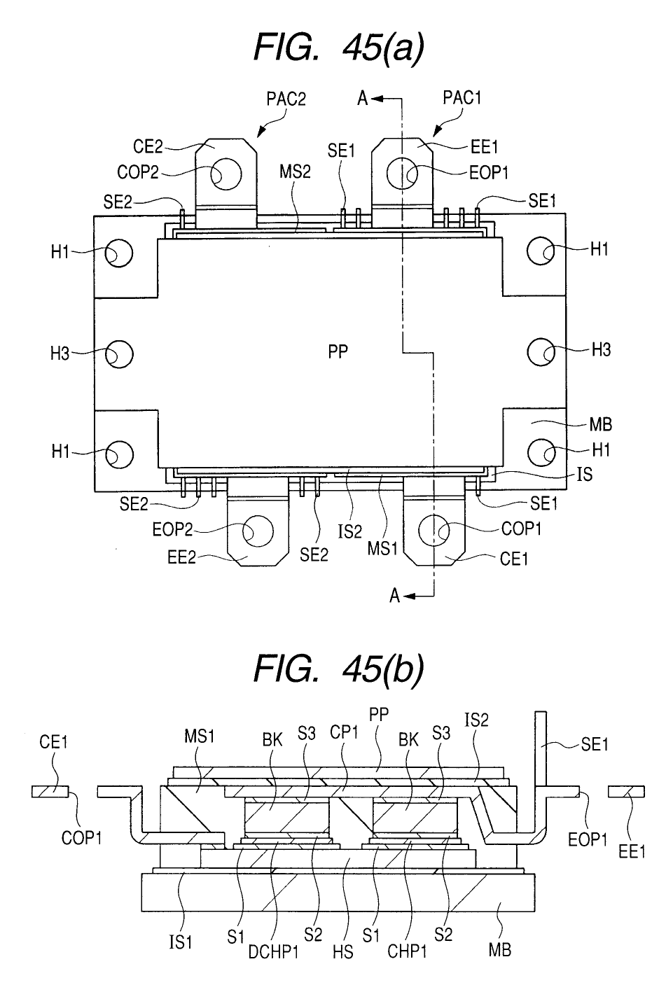

Subsequently, as shown in FIGS. 45A and 45B, the pressing plate PP is mounted in such a manner as to extend across over the single package PAC1 and over the single package PAC2 via the insulation sheet IS2 (S306 of FIG. 40). In the pressing plate PP, the pressing plate fixing screw holes H3 are formed. The pressing plate PP is disposed such that the pressing plate fixing screw holes H3 formed in the pressing plate PP overlap the pressing plate fixing screw holes H3 formed in the metal board MB in plan view, respectively.

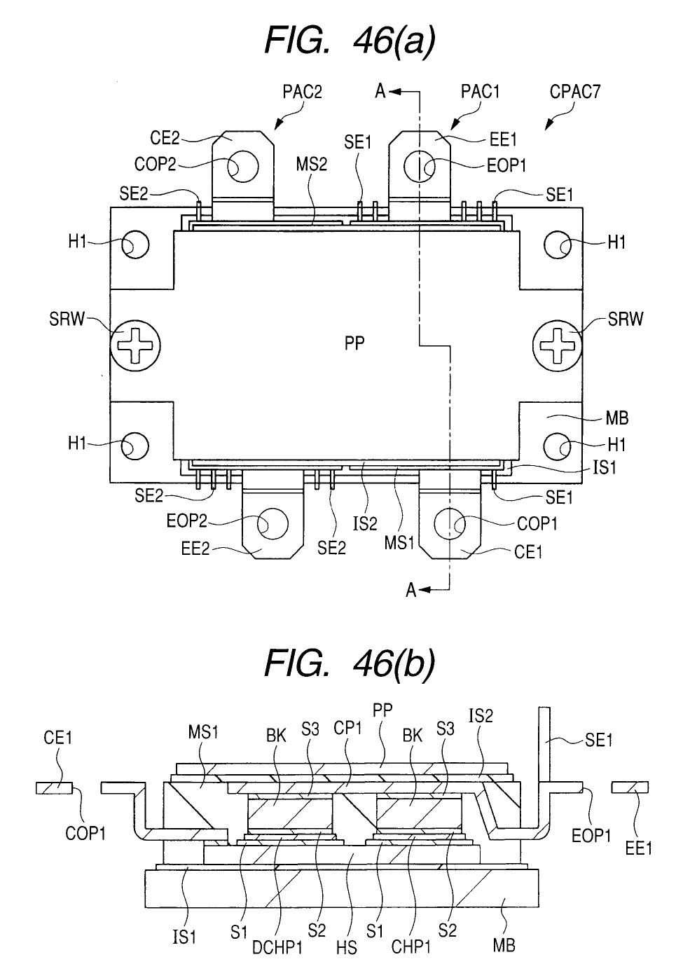

Then, as shown in FIGS. 46A and 46B, the pressing plate PP is fixed to the metal board MB by the pressing plate fixing screws SRW (S307 of FIG. 40). Namely, by inserting the pressing plate fixing screws SRW into both of the pressing plate fixing screw holes H3 formed in the pressing plate PP, and the pressing plate fixing screw holes H3 formed in the metal board MB, the pressing plate PP is fixed to the metal board MB.

In the foregoing manner, the composite package CPAC7 can be manufactured. Then, the completed composite package CPAC7 is supplied to a customer, and is mounted in the housing cover of a three-phase motor, or the like on the part of the customer.

### Embodiment 8

In Embodiment 8, a description will be given to a composite package CPAC9 including three single packages PAC mounted therein.

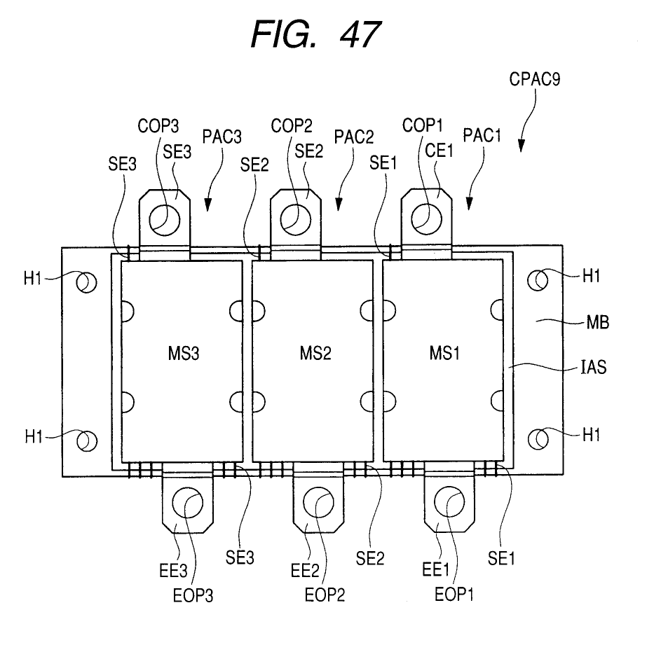

FIG. 47 is a plan view showing the configuration of the composite package CPAC9 in Embodiment 8. In FIG. 47, the composite package CPAC9 in Embodiment 8 has the metal board MB in the shape of a rectangle. Over the surface of the metal board MB, an insulation layer (not shown) is formed. Over the metal board MB over which the insulation layer is formed, an insulation adhesion sheet IAS is formed. Then, over the insulation adhesion sheet IAS, single packages PAC1 to PAC3 are mounted.

The metal board MB is formed of a material with a good thermal conductivity such as an aluminum board or a copper board. In a region outside the region including the single packages PAC1 to PAC3 mounted therein of the region of the metal board MB, the metal board fixing screw holes H1 are formed. The metal board fixing screw holes H1 are formed in the four corners of the metal board MB in the shape of a rectangle.

The insulation adhesion sheet IAS formed over the metal board MB includes, for example, a thermosetting resin. Specifically, the insulation adhesion sheet IAS is in a structure in which a base resin including a silicone resin or an epoxy resin is filled with a filler including ceramics such as aluminum oxide (Al₂O₃) or boron nitride or glass cloth.

The single packages PAC1 to PAC3 have the structure described by reference to FIGS. 2 to 5 of Embodiment 1. Specifically, as shown in FIG. 47, in the central part of the single package PAC1, the sealing body MS1 in the shape of generally a rectangle in plan view is formed. At the top of the sealing body MS1, there are provided the external coupling collector electrode CE1 and some of the signal electrodes SE1. Then, at the bottom of the sealing body MS1 opposite to the top thereof at which the external coupling collector electrode CE1 is formed, there are formed the external coupling emitter electrode EE1 and others of the signal electrodes SE1. Then, in the external coupling collector electrode CE1, a screw opening COP1 is formed. In the external coupling emitter electrode EE1, a screw opening EOP1 is formed.

Similarly, in the central part of the single package PAC2, the sealing body MS2 in the shape of generally a rectangle in plan view is formed. At the top of the sealing body MS2, there are provided the external coupling collector electrode CE2 and some of the signal electrodes SE2. Then, at the bottom of the sealing body MS2 opposite to the top thereof at which the external coupling collector electrode CE2 is formed, there are formed the external coupling emitter electrode EE2 and others of the signal electrodes SE2. Then, in the external coupling collector electrode CE2, a screw opening COP2 is formed. In the external coupling emitter electrode EE2, a screw opening EOP2 is formed.

Further, in the central part of the single package PAC3, the sealing body MS3 in the shape of generally a rectangle in plan view is formed. At the top of the sealing body MS3, there are provided the external coupling collector electrode CE3 and some of the signal electrodes SE3. Then, at the bottom of the sealing body MS2 opposite to the top thereof at which the external coupling collector electrode CE3 is formed, there are formed the external coupling emitter electrode EE3 and others of the signal electrodes SE3. Then, in the external coupling collector electrode CE3, a screw opening COPS is formed. In the external coupling emitter electrode EE3, a screw opening EOP3 is formed.

The thus formed composite package CPAC9 has a feature in that over the metal board MB, the single packages PAC1 to PAC3 are mounted together to form one composite package CPAC9. As a result, as compared with the case where six single packages are mounted, the number of packages to be mounted becomes smaller in the case where two composite packages CPAC9 are mounted. This can reduce the mounting burden on the part of a customer. Namely, when the single packages are mounted on the part of a customer, one three-phase motor requires mounting of six single packages therein. However, when the composite packages CPAC9 are mounted on the part of a customer, one three-phase motor requires mounting of only two composite packages CPAC9. Therefore, by supplying the composite packages CPAC9 to a customer, it is possible to obtain an effect of allowing a large reduction of the mounting burden on the part of the customer.

Further, the composite package CPAC9 in Embodiment 8 has a feature in that the directions of mounting of the single packages PAC1 to PAC3 mounted over the metal board MB are the same. In other words, as shown in FIG. 47, in the composite package CPAC9 in Embodiment 9, the single packages PAC1 to PAC3 are disposed over the insulation adhesion sheet IAS such that the external coupling collector electrode CE1 protruding from the sealing body MS1, the external coupling collector electrode CE2 protruding from the sealing body MS2, and the external coupling collector electrode CE3 protruding from the sealing body MS3 are disposed adjacent to one another on the side of the same side of the metal board MB. This can reduce the mounting burden on the part of a customer.

For example, the single packages PAC1 to PAC3 to be mounted in a first composite package CPAC9 can be each configured as a package including the IGBT 4 and the diode 5 sealed therein to be coupled between the power supply potential (Vcc) and the three-phase motor shown in FIG. 1. Then, the single packages PAC1 to PAC3 to be mounted in a second composite package CPAC9 can be each configured as a package including the IGBT 4 and the diode 5 sealed therein to be coupled between the ground potential (GND) and the three-phase motor shown in FIG. 1. In this case, with the first composite package CPAC9 and the second composite package CPAC9, the power semiconductor device 2 shown in FIG. 1 can be configured of two composite packages CPAC9 having the same configuration.

As indicated from FIG. 1, the collector electrodes of the IGBTs 4 coupled between the power supply potential (Vcc) and the three-phase motor are in common among the three IGBTs 4. This means that the external coupling collector electrodes CE1 to CE3 of the single packages PAC1 to PAC3 mounted in the first composite package CPAC9 are coupled to one another. Similarly, the emitter electrodes of the IGBTs 4 coupled between the ground potential (GND) and the three-phase motor are in common among the three IGBTs 4. This means that the external coupling emitter electrodes EE1 to EE3 of the single packages PAC1 to PAC3 mounted in the second composite package CPAC9 are coupled to one another.

Therefore, the single packages PAC1 to PAC3 are disposed such that the external coupling collector electrodes CE1 to CE3 of the single packages PAC1 to PAC3 are disposed on the side of the same side of the metal board MB. In other words, the single packages PAC1 to PAC3 are disposed such that the external coupling emitter electrodes EE1 to EE3 of the single packages PAC1 to PAC3 are disposed on the side of the same side of the metal board MB. This facilitates coupling of the external coupling collector electrodes CE1 to CE3 of the single packages PAC1 to PAC3 in mounting on the part of a customer. In other words, the composite package CPAC9 in Embodiment 8 has an advantage in that unification of directions of mounting of the single packages PAC1 to PAC3 mounted over the metal board MB facilitates the mounting layout on the part of a customer.

The composite package CPAC9 in Embodiment 8 is configured as described above. The manufacturing method thereof is the same as that in Embodiment 2. Incidentally, for the composite package CPAC9 in Embodiment 8, a description was given to the example in which using the insulation adhesion sheet IAS, the single packages PAC1 to PAC3 are mounted over the metal board MB. However, for example, as in Embodiment 3, using the pressing plate PP, the single packages PAC1 to PAC3 may be fixed to the top of the metal board MB.

### Embodiment 9

In Embodiment 9, a description will be given to a composite package CPAC10 including six single packages PAC mounted therein.

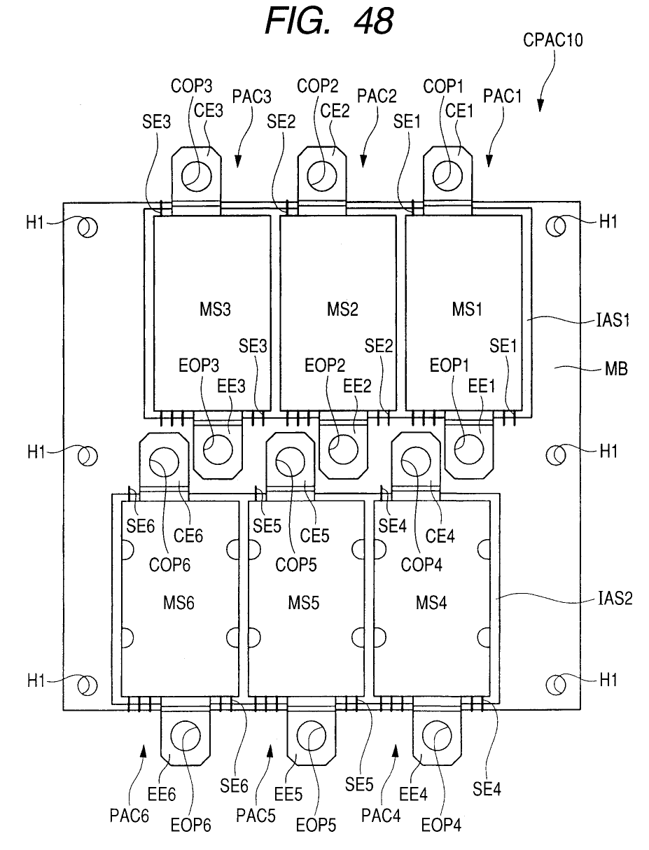

FIG. 48 is a plan view showing the configuration of the composite package CPAC10 in Embodiment 9. In FIG. 48, the composite package CPAC10 in Embodiment 9 has the metal board MB in the shape of a rectangle. Over the surface of the metal board MB, an insulation layer (not shown) is formed. Over the metal board MB including the insulation layer formed thereover, an insulation adhesion sheet IAS1 and an insulation adhesion sheet IAS2 are formed. Then, over the insulation adhesion sheet IAS1, single packages PAC1 to PAC3 are mounted. Over the insulation adhesion sheet IAS2, the single packages PAC4 to PAC6 are mounted.

The metal board MB is formed of a material with a good thermal conductivity such as an aluminum board or a copper board. In a region outside the region including the single packages PAC1 to PAC6 mounted therein of the region of the metal board MB, the metal board fixing screw holes H1 are formed. The metal board fixing screw holes H1 are formed along the sides of the metal board MB in the shape of a rectangle.

The insulation adhesion sheet IAS1 and the insulation adhesion sheet IAS2 formed over the metal board MB include, for example, a thermosetting resin. Specifically, the insulation adhesion sheet IAS1 and the insulation adhesion sheet IAS2 are each in a structure in which a base resin including a silicone resin or an epoxy resin is filled with a filler including ceramics such as aluminum oxide (Al₂O₃) or boron nitride or glass cloth.

The single packages PAC1 to PAC6 each have the structure described with reference to FIGS. 2 to 5 in Embodiment 1. Specifically, as shown in FIG. 48, in the central parts of the single packages PAC1 to PAC6, the sealing bodies MS1 to MS6 each in the shape of generally a rectangle in plan view are formed, respectively. At the tops of the sealing bodies MS1 to MS6, there are provided external coupling collector electrodes CE1 to CE6 and some of signal electrodes SE1 to SE6, respectively. Then, at the bottoms of the sealing bodies MS1 to MS6 opposite to their respective tops thereof at which the external coupling collector electrodes CE1 to CE6 are formed, there are formed external coupling emitter electrodes EE1 to EE6 and others of the signal electrodes SE1 to SE6, respectively. Then, in the external coupling collector electrodes CE1 to CE6, screw openings COP1 to COP6 are formed, respectively. In the external coupling emitter electrodes EE1 to EE6, screw openings EOP1 to EOP6 are formed, respectively.

The thus formed composite package CPAC10 has a feature in that, over the metal board MB, the single packages PAC1 to PAC6 are mounted together to form one composite package CPAC10. As a result, as compared with the case where six single packages are mounted, the number of packages to be mounted becomes smaller in the case where one composite package CPAC10 is mounted. This can reduce the mounting burden on the part of a customer. Namely, when the single packages are mounted on the part of a customer, one three-phase motor requires mounting of six single packages therein. However, when the composite package CPAC10 is mounted on the part of a customer, one three-phase motor requires mounting of only one composite package CPAC10. Therefore, by supplying the composite package CPAC10 to a customer, it is possible to obtain an effect of allowing a large reduction of the mounting burden on the part of a customer.

The composite package CPAC10 in Embodiment 9 is configured as described above. The manufacturing method thereof is the same as that in Embodiment 2. Incidentally, for the composite package CPAC10 in Embodiment 9, a description was given to the example in which using the insulation adhesion sheet IAS1 and the insulation adhesion sheet IAS2, the single packages PAC1 to PAC6 are mounted over the metal board MB. However, for example, as in Embodiment 3, using the pressing plate PP, the single packages PAC1 to PAC6 may be fixed to the top of the metal board MB.

### Embodiment 10

In Embodiment 10, a description will be given to a mounting example in which, on the part of a customer, composite packages are mounted to form a power semiconductor device controlling a three-phase motor.

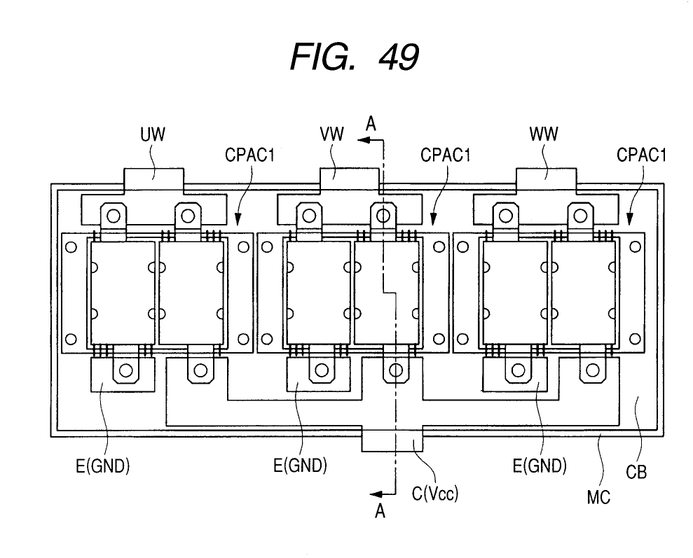

FIG. 49 is a view showing a mounting example in which, using the composite packages CPAC1 described in Embodiment 1, the power semiconductor device 2 shown in FIG. 1 is formed. As shown in FIG. 49, in a resin case MC, three composite packages CPAC1 are disposed. The three composite packages CPAC1 are respectively disposed in such a manner as to be coupled to a collector wire C (Vcc), an emitter wire E (GND), a U-phase wire UW, a V-phase wire VW, and a W-phase wire WW. As a result, it is possible to form the power semiconductor device 2 including six IGBTs 4 and six diodes 5 shown in FIG. 1. Then, the power semiconductor device 2 is disposed in the resin case MC, and above the three composite packages CPAC1, a control board CB is disposed.

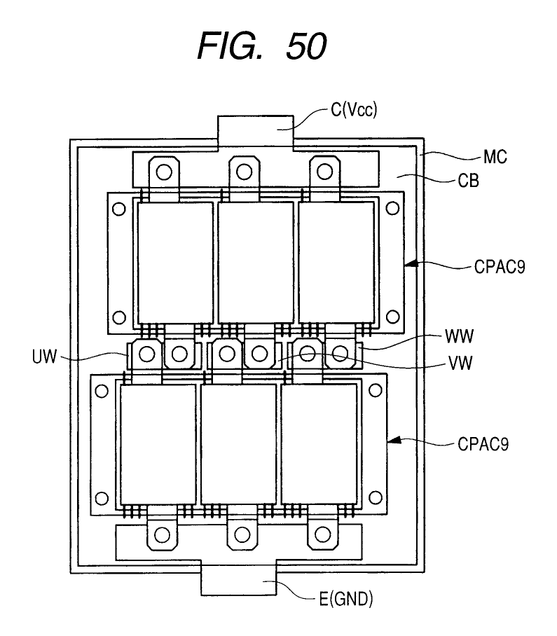

Then, FIG. 50 is a view showing a mounting example in which, using the composite packages CPAC9 described in Embodiment 8, the power semiconductor device 2 shown in FIG. 1 is formed. As shown in FIG. 50, in the resin case MC, two composite packages CPAC9 are disposed. The two composite packages CPAC9 are respectively disposed in such a manner as to be coupled with a collector wire C (Vcc), an emitter wire E (GND), a U-phase wire UW, a V-phase wire VW, and a W-phase wire WW. As a result, it is possible to form the power semiconductor device 2 including six IGBTs 4 and six diodes 5 shown in FIG. 1. Then, the power semiconductor device 2 is disposed in the resin case MC, and above the two composite packages CPAC9, a control board CB is disposed.

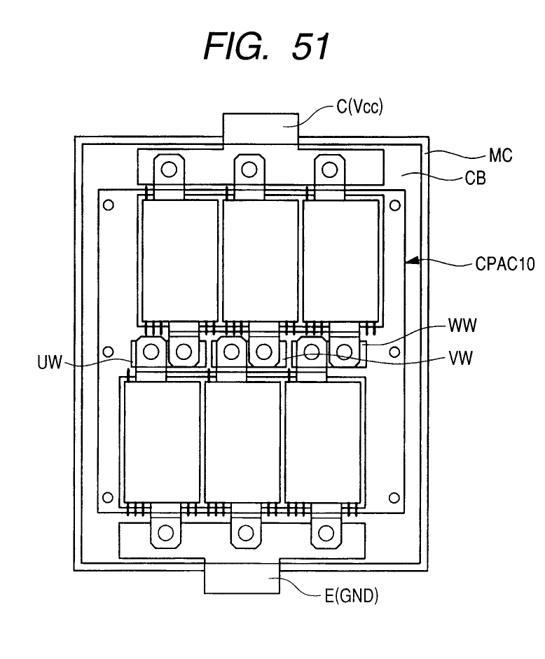

Subsequently, FIG. 51 is a view showing a mounting example in which, using the composite package CPAC10 described in Embodiment 9, the power semiconductor device 2 shown in FIG. 1 is formed. As shown in FIG. 51, in the resin case MC, one composite package CPAC10 is disposed. The one composite package CPAC10 is disposed in such a manner as to be coupled with a collector wire C (Vcc), an emitter wire E (GND), a U-phase wire UW, a V-phase wire VW, and a W-phase wire WW. As a result, it is possible to form the power semiconductor device 2 including six IGBTs 4 and six diodes 5 shown in FIG. 1. Then, the power semiconductor device 2 is disposed in the resin case MC, and above the one composite package CPAC10, a control board CB is disposed.

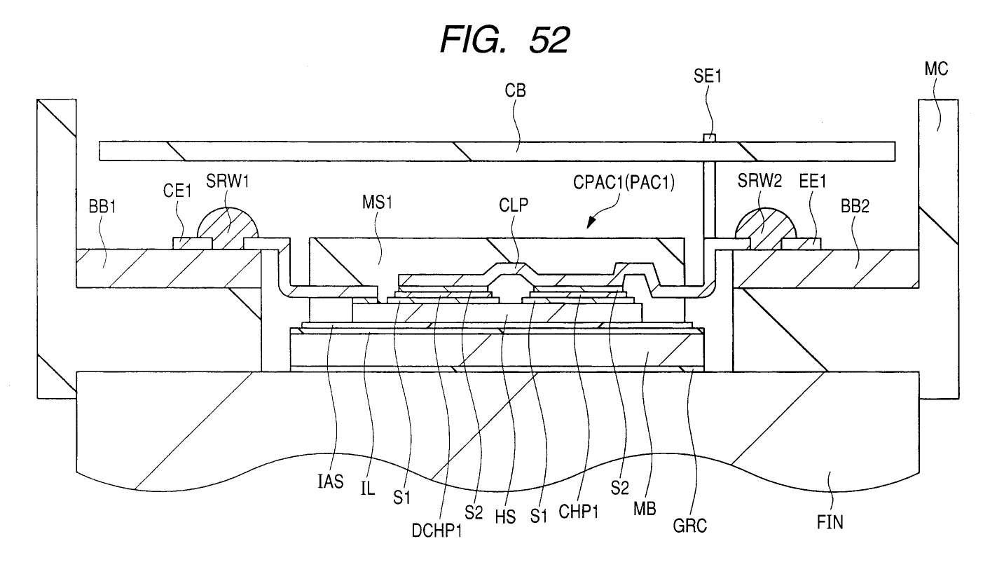

Then, a description will be given to the cross-sectional structure of a structure including the composite package CPAC1 shown in FIG. 49 mounted therein. FIG. 52 is a cross-sectional view cut along line A-A of FIG. 49. As shown in FIG. 52, for example, at the bottom of the resin case MC, a radiating fin FIN including aluminum is attached. In the concave part formed in the central part of the resin case MC, the single packages PAC1 forming the composite package CPAC1 are mounted. The composite package CPAC1 is in contact with the radiating fin FIN via a grease GRC. Thus, the heat generated in the composite package CPAC1 transmits to the radiating fin FIN, so that the heat can be dissipated with efficiency.

Over the radiating fin FIN, the composite package CPAC1 is mounted via the grease GRC. Specifically, over the grease GRC, the metal board MB is disposed. Over the surface of the metal board MB, the insulation layer IL is formed. Over the insulation layer IL, the insulation adhesion sheet IAS is formed. Over the insulation adhesion sheet IAS, the sealing body MS1 is disposed. The insulation adhesion sheet IAS is in contact with the heat spreader HS exposed from the back surface of the sealing body MS1.

The heat spreader HS is coupled with the external coupling collector electrode CE1. The external coupling collector electrode CE1 is fixed to a bus bar BB1 by a screw SRW1. The bus bar BB1 is coupled with the collector wire C (Vcc) shown in FIG. 49. Further, over the heat spreader HS, the semiconductor chip DCHP1 including a diode formed therein and the semiconductor chip CHP1 including an IGBT formed therein are mounted via the solder S1. Over the semiconductor chip DCHP1 and the semiconductor chip CHP1, the clip CLP is mounted via the solder S2. The clip CLP is coupled with the external coupling emitter electrode EE1. The external coupling emitter electrode EE1 is coupled with a bus bar BB2 by a screw SRW2. The bus bar BB2 is coupled with the V-phase wire VW shown in FIG. 49.

Further, from the sealing body MS1, the signal electrodes SE1 protrude upwardly. The signal electrodes SE1 are inserted into the control board CB disposed above the composite package CPAC1, and coupled with the control board CB by solder or the like. The signal electrodes SE1 include, for example, the external coupling gate electrode GE, the temperature detecting electrodes TE1 and TE2, the current detecting electrode IE, or the Kelvin detecting electrodes KE1 and KE2. The signal electrodes SE1 are coupled with the control circuit, the current detecting circuit, the temperature detecting circuit, and the Kelvin detecting circuit, mounted over the control board CB. As described up to this point, the power semiconductor device 2 shown in FIG. 1 is mounted and formed.

Up to this point, the invention made by the present inventors was specifically described by way of embodiments thereof. However, the present invention is not limited to the embodiments. It is naturally understood that various changes may be made within the scope not departing from the gist thereof.

In Embodiments 1 to 10, a description was given to the examples in which IGBTs were used as switching elements. However, as the switching elements, power MISFETs (Metal Insulator Semiconductor Field Effect Transistors) can also be used. In this case, the external coupling collector electrode of the package functions as an external coupling drain electrode, and the external coupling emitter electrode functions as an external coupling source electrode.

### INDUSTRIAL APPLICABILITY

The present invention can be widely used for manufacturers manufacturing semiconductor devices.

What is claimed is:

1. A semiconductor device, comprising:
a first package including a first semiconductor chip including a first switching element formed therein and a first diode chip including a first diode formed therein, and a first sealing body, the first semiconductor chip and the first diode chip being sealed with the first sealing body; and
a second package including a second semiconductor chip including a second switching element formed therein and a second diode chip including a second diode formed therein, and a second sealing body, the second semiconductor chip and the second diode chip being sealed with the second sealing body,
wherein the first package includes:
(a1) a first external coupling emitter electrode protruding from a first side of the first sealing body;
(a2) a first external coupling collector electrode protruding from a second side of the first sealing body opposite to the first side thereof; and
(a3) a first external coupling gate electrode protruding from the first side of the first sealing body, and
wherein the second package includes:
(b1) a second external coupling emitter electrode protruding from a first side of the second sealing body;
(b2) a second external coupling collector electrode protruding from a second side of the second sealing body opposite to the first side thereof; and
(b3) a second external coupling gate electrode protruding from the first side of the second sealing body,
the semiconductor device, comprising:
(c) a metal board including an insulation layer formed over the surface thereof;
(d) the first package mounted over the insulation layer via an insulation adhesion layer;
(e) the second package mounted over the insulation layer via the insulation adhesion layer; and
(f) a metal board fixing screw hole formed in the metal board.

2. The semiconductor device according to claim 1, wherein in a region outside the region including the first package and the second package mounted therein of, the region of the metal board, the metal board fixing screw hole is formed.

3. The semiconductor device according to claim 1, wherein in a region between the region including the first package mounted therein and the region including the second package mounted therein, of the region of the metal board, the metal board fixing screw hole is formed.

4. The semiconductor device according to claim 1, wherein the first package and the second package are disposed over the insulation adhesion layer such that the first external coupling emitter electrode protruding from the first side of the first sealing body, and the second external coupling collector electrode protruding from the second side of the second sealing body are disposed adjacent to each other on the side of the same side of the metal board.

5. The semiconductor device according to claim 1, wherein the insulation adhesion layer is a layer including a base resin layer filled with a filler.

6. The semiconductor device according to claim 5,
wherein the base resin layer is formed of an epoxy resin or a silicone resin, and
wherein the filler is formed of aluminum oxide or boron nitride.

7. The semiconductor device according to claim 1, further comprising:
a first heat spreader including the first semiconductor chip and the first diode chip mounted thereover, and electrically coupled with the first external coupling collector electrode; and
a second heat spreader including the second semiconductor chip and the second diode chip mounted thereover, and electrically coupled with the second external coupling collector electrode,
wherein the bottom surface of the first heat spreader is exposed from the bottom surface of the first sealing body, and
wherein the bottom surface of the second heat spreader is exposed from the bottom surface of the second sealing body.

8. The semiconductor device according to claim 7, further comprising:
a first conductive member directly or indirectly coupled with the first semiconductor chip and the first diode chip, and electrically coupled with the first external coupling emitter electrode; and
a second conductive member directly or indirectly coupled with the second semiconductor chip and the second diode chip, and electrically coupled with the second external coupling emitter electrode,
wherein the top surface of the first conductive member is exposed from the top surface of the first sealing body opposite to the bottom surface thereof, and
wherein the top surface of the second conductive member is exposed from the top surface of the second sealing body opposite to the bottom surface thereof.

9. A semiconductor device, comprising:
a first package including a first semiconductor chip including a first switching element formed therein and a first diode chip including a first diode formed therein, and a first sealing body, the first semiconductor chip and the first diode chip being sealed with the first sealing body; and
a second package including a second semiconductor chip including a second switching element formed therein and a second diode chip including a second diode formed therein, and a second sealing body, the second semiconductor chip and the second diode chip being sealed with the second sealing body,
wherein the first package includes:
(a1) a first external coupling emitter electrode protruding from a first side of the first sealing body;
(a2) a first external coupling collector electrode protruding from a second side of the first sealing body opposite to the first side thereof, and
(a3) a first external coupling gate electrode protruding from the first side of the first sealing body; and
wherein the second package has (b1) a second external coupling emitter electrode protruding from a first side of the second sealing body, (b2) a second external coupling collector electrode protruding from a second side of the second sealing body opposite to the first side thereof, and (b3) a second external coupling gate electrode protruding from the first side of the second sealing body,
the semiconductor device, comprising:
(c) a metal board;
(d) a first insulation sheet mounted over the metal board;
(e) the first package mounted over the first insulation sheet;
(f) the second package mounted over the first insulation sheet;
(g) a pressing plate disposed across over the first package and over the second package;
(h) a metal board fixing screw hole formed in the metal board;
(i) a first pressing plate fixing screw hole formed in the metal board;
(j) a second pressing plate fixing screw hole formed in the pressing plate; and
(k) a pressing plate fixing screw to be inserted into both of the first pressing plate fixing screw hole and the second pressing plate fixing screw hole, for fixing the pressing plate to the metal board.

10. The semiconductor device according to claim 9,
wherein in a region outside the region including the first package and the second package mounted therein, of the region of the metal board, the metal board fixing screw hole and the first pressing plate fixing screw hole are formed, and
wherein in a region overlapping the first pressing plate fixing screw hole formed in the metal board in plan view of the region of the pressing plate, the second pressing plate fixing screw hole is formed.

11. The semiconductor device according to claim 9,
wherein in a region between the region including the first package mounted therein and the region including the second package mounted therein, of the region of the metal board, the metal board fixing screw hole and the first pressing plate fixing screw hole are formed, and
wherein in a region overlapping the first pressing plate fixing screw hole formed in the metal board in plan view of the region of the pressing plate, the second pressing plate fixing screw hole is formed.

12. The semiconductor device according to claim 9, wherein the first package and the second package are disposed over the metal board such that the first external coupling emitter electrode protruding from the first side of the first sealing body, and the second external coupling collector electrode protruding from the second side of the second sealing body are disposed adjacent to each other on the side of the same side of the metal board.

13. The semiconductor device according to claim 9, wherein the first insulation sheet is a sheet including a base resin filled with a filler.

14. The semiconductor device according to claim 13,
wherein the base resin is formed of an epoxy resin or a silicone resin, and
wherein the filler is formed of aluminum oxide or boron nitride.

15. The semiconductor device according to claim 9, further comprising:
a first heat spreader including the first semiconductor chip and the first diode chip mounted thereover, and electrically coupled with the first external coupling collector electrode; and
a second heat spreader including the second semiconductor chip and the second diode chip mounted thereover, and electrically coupled with the second external coupling collector electrode,
wherein the bottom surface of the first heat spreader is exposed from the bottom surface of the first sealing body, and
wherein the bottom surface of the second heat spreader is exposed from the bottom surface of the second sealing body.

16. The semiconductor device according to claim 15, further comprising:
a first conductive member directly or indirectly coupled with the first semiconductor chip and the first diode chip, and electrically coupled with the first external coupling emitter electrode;
a second conductive member directly or indirectly coupled with the second semiconductor chip and the second diode chip, and electrically coupled with the second external coupling emitter electrode; and
a second insulation sheet disposed between the top surface of the first package and the pressing plate, and between the top surface of the second package and the pressing plate,
wherein the top surface of the first conductive member is exposed from the top surface of the first sealing body opposite to the bottom surface thereof, and
wherein the top surface of the second conductive member is exposed from the top surface of the second sealing body opposite to the bottom surface thereof.

17. A method for manufacturing a semiconductor device, comprising the steps of:
(a) preparing a first package including a first semiconductor chip including a first switching element formed therein and a first diode chip including a first diode formed therein, and a first sealing body, the first semiconductor chip and the first diode chip being sealed with the first sealing body;
(b) preparing a second package including a second semiconductor chip including a second switching element formed therein and a second diode chip including a second diode formed therein, and a second sealing body, the second semiconductor chip and the second diode chip being sealed with the second sealing body;
(c) preparing a metal board including an insulation layer over the surface thereof;
(d) forming an insulation adhesion layer over the insulation layer formed over the metal board;
(e) mounting the first package and the second package over the insulation adhesion layer; and
(f) curing the insulation adhesion layer, and thereby bonding the insulation layer with the first package, and the insulation layer with the second package.

18. The method for manufacturing a semiconductor device according to claim 17,
wherein the first package has a first external coupling emitter electrode protruding from a first side of the first sealing body, a first external coupling collector electrode protruding from a second side of the first sealing body opposite to the first side thereof, and a first external coupling gate electrode protruding from the first side of the first sealing body,
wherein the second package has a second external coupling emitter electrode protruding from a first side of the second sealing body, a second external coupling collector electrode protruding from a second side of the second sealing body opposite to the first side thereof, and a second external coupling gate electrode protruding from the first side of the second sealing body, and
wherein the step (e) includes: disposing the first package and the second package over the insulation adhesion layer such that the first external coupling emitter electrode protruding from the first side of the first sealing body and the second external coupling collector electrode protruding from the second side of the second sealing body are disposed adjacent to each other on the side of the same side of the metal board.

19. A method for manufacturing a semiconductor device, comprising the steps of:
(a) preparing a first package including a first semiconductor chip including a first switching element formed therein and a first diode chip including a first diode formed therein, and a first sealing body, the first semiconductor chip and the first diode chip being sealed with the first sealing body;
(b) preparing a second package including a second semiconductor chip including a second switching element formed therein and a second diode chip including a second diode formed therein, and a second sealing body, the second semiconductor chip and the second diode chip being sealed with the second sealing body;
(c) preparing a metal board including a metal board fixing screw hole and a first pressing plate fixing screw hole formed therein;
(d) mounting an insulation sheet over the metal board;
(e) mounting the first package and the second package over the insulation sheet;
(f) mounting a pressing plate including a second pressing plate fixing screw hole formed therein across over the first package and over the second package, and disposing the pressing plate such that the second pressing plate fixing screw hole overlaps the first pressing plate fixing screw hole in plan view; and
(g) inserting a pressing plate fixing screw into the second pressing plate fixing screw hole and the first pressing plate fixing screw hole, and fixing the pressing plate to the metal board.

20. The method for manufacturing a semiconductor device according to claim 19,
wherein the first package has a first external coupling emitter electrode protruding from a first side of the first sealing body, a first external coupling collector electrode protruding from a second side of the first sealing body opposite to the first side thereof, and a first external coupling gate electrode protruding from the first side of the first sealing body,
wherein the second package has a second external coupling emitter electrode protruding from a first side of the second sealing body, a second external coupling collector electrode protruding from a second side of the second sealing body opposite to the first side thereof, and a second external coupling gate electrode protruding from the first side of the second sealing body, and
wherein the step (e) includes: disposing the first package and the second package over the insulation sheet such that the first external coupling emitter electrode protruding from the first side of the first sealing body and the second external coupling collector electrode protruding from the second side of the second sealing body are disposed adjacent to each other on the side of the same side of the metal board.

21. A method for manufacturing a semiconductor device,
the semiconductor device comprising: a first package including a first semiconductor chip including a first switching element formed therein and a first diode chip including a first diode formed therein, and a first sealing body, the first semiconductor chip and the first diode chip being sealed with the first sealing body; and a second package including a second semiconductor chip including a second switching element formed therein and a second diode chip including a second diode formed therein, and a second sealing body, the second semiconductor chip and the second diode chip being sealed with the second sealing body,
wherein the first package includes: a first external coupling emitter electrode protruding from a first side of the first sealing body; a first external coupling collector electrode protruding from a second side of the first sealing body opposite to the first side thereof; and a first external coupling gate electrode protruding from the first side of the first sealing body, and
wherein the second package includes: a second external coupling emitter electrode protruding from a first side of the second sealing body; a second external coupling collector electrode protruding from a second side of the second sealing body opposite to the first side thereof; and a second external coupling gate electrode protruding from the first side of the second sealing body,
the method comprising the steps of:
(a) preparing the first package in which the bottom surface of a first heat spreader including the first semiconductor chip and the first diode chip mounted thereover, and electrically coupled with the first external coupling collector electrode is exposed from the bottom surface of the first sealing body, and the top surface of a first conductive member directly or indirectly coupled with the first semiconductor chip and the first diode chip, and electrically coupled with the first external coupling emitter electrode is exposed from the top surface of the first sealing body opposite to the bottom surface thereof;
(b) preparing the second package in which the bottom surface of a second heat spreader including the second semiconductor chip and the second diode chip mounted thereover, and electrically coupled with the second external coupling collector electrode is exposed from the bottom surface of the second sealing body, and the top surface of a second conductive member directly or indirectly coupled with the second semiconductor chip and the second diode chip, and electrically coupled with the second external coupling emitter electrode is exposed from the top surface of the second sealing body opposite to the bottom surface thereof;
(c) preparing a metal board including a metal board fixing screw hole and a first pressing plate fixing screw hole formed therein;
(d) mounting a first insulation sheet over the metal board;
(e) mounting the first package and the second package over the first insulation sheet such that the bottom surface of the first package and the bottom surface of the second package are in contact with the first insulation sheet;
(f) mounting a second insulation sheet across over the top surface of the first package and over the top surface of the second package;
(g) mounting a pressing plate including a second pressing plate fixing screw hole formed therein over the second insulation sheet, and disposing the pressing plate such that the second pressing plate fixing screw hole overlaps the first pressing plate fixing screw hole in plan view; and
(h) inserting a pressing plate fixing screw into the second pressing plate fixing screw hole and the first pressing plate fixing screw hole, and fixing the pressing plate to the metal board.

22. The method for manufacturing a semiconductor device according to claim 21, wherein the step (e) includes: disposing the first package and the second package over the first insulation sheet such that the first external coupling emitter electrode protruding from the first side of the first sealing body and the second external coupling collector electrode protruding from the second side of the second sealing body are disposed adjacent to each other on the side of the same side of the metal board.

23. A semiconductor device, comprising:
a first package including a first semiconductor chip including a first switching element formed therein and a first diode chip including a first diode formed therein, and a first sealing body, the first semiconductor chip and the first diode chip being sealed with the first sealing body; and
a second package including a second semiconductor chip including a second switching element formed therein and a second diode chip including a second diode formed therein, and a second sealing body, the second semiconductor chip and the second diode chip being sealed with the second sealing body,
wherein the first package includes:
(a1) a first external coupling source electrode protruding from a first side of the first sealing body;
(a2) a first external coupling drain electrode protruding from a second side of the first sealing body opposite to the first side thereof; and
(a3) a first external coupling gate electrode protruding from the first side of the first sealing body, and
wherein the second package includes:
(b1) a second external coupling source electrode protruding from a first side of the second sealing body;
(b2) a second external coupling drain electrode protruding from a second side of the second sealing body opposite to the first side thereof; and
(b3) a second external coupling gate electrode protruding from the first side of the second sealing body,
the semiconductor device, comprising:
(c) a metal board including an insulation layer over the surface thereof;
(d) the first package mounted over the insulation layer via an insulation adhesion layer;
(e) the second package mounted over the insulation layer via the insulation adhesion layer; and
(f) a metal board fixing screw hole formed in the metal board.

24. A semiconductor device, comprising:
a first package including a first semiconductor chip including a first switching element formed therein and a first diode chip including a first diode formed therein, and a first sealing body, the first semiconductor chip and the first diode chip being sealed with the first sealing body; and
a second package including a second semiconductor chip including a second switching element formed therein and a second diode chip including a second diode formed therein, and a second sealing body, the second semiconductor chip and the second diode chip being sealed with the second sealing body,
wherein the first package includes:
(a1) a first external coupling source electrode protruding from a first side of the first sealing body;
(a2) a first external coupling drain electrode protruding from a second side of the first sealing body opposite to the first side thereof; and
(a3) a first external coupling gate electrode protruding from the first side of the first sealing body, and
wherein the second package includes:
(b1) a second external coupling source electrode protruding from a first side of the second sealing body;
(b2) a second external coupling drain electrode protruding from a second side of the second sealing body opposite to the first side thereof; and
(b3) a second external coupling gate electrode protruding from the first side of the second sealing body,
the semiconductor device, comprising:
(c) a metal board;
(d) a first insulation sheet mounted over the metal board;
(e) the first package mounted over the first insulation sheet;
(f) the second package mounted over the first insulation sheet;
(g) a pressing plate disposed across over the first package and over the second package;
(h) a metal board fixing screw hole formed in the metal board;
(i) a first pressing plate fixing screw hole formed in the metal board;
(j) a second pressing plate fixing screw hole formed in the pressing plate; and
(k) a pressing plate fixing screw to be inserted into both of the first pressing plate fixing screw hole and the second pressing plate fixing screw hole, for fixing the pressing plate to the metal board.
